(19) United States
(12) Patent Application Publication
(10) Pub. No.: US 2023/0039270 A1
(43) Pub. Date: Feb. 9, 2023

(54) SOLID-STATE IMAGING DEVICE AND DISTANCE MEASURING DEVICE

(71) Applicant: SONY SEMICONDUCTOR SOLUTIONS CORPORATION, KANAGAWA (JP)

(72) Inventors: ATSUMI NIWA, KANAGAWA (JP); MOTONARI HONDA, KANAGAWA (JP)

(21) Appl. No.: 17/756,844

(22) PCT Filed: Dec. 10, 2020
(86) PCT No.: PCT/JP2020/046008

§ 371 Date: Jun. 3, 2022

(30) Foreign Application Priority Data
Dec. 17, 2019 (JP) 2019-226946

(51) Int. Cl. G01S 17/89; G01S 7/481; H04N 5/376; H04N 5/369; H04N 5/351; H04N 5/357

(52) U.S. Cl. CPC G01S 17/89; G01S 7/4816; H04N 5/3765; H04N 5/36965; H04N 5/351; H04N 5/357; H04N 5/379

(57) ABSTRACT

Distance measurement accuracy is improved while an increase in power consumption is suppressed. A solid-state imaging device includes a first pixel (210) that detects an address event based on incident light, and a second pixel (310) that generates information on a distance to an object based on the incident light. The second pixel generates the information on the distance to the object when the first pixel detects the address event.

### FIELD

The present disclosure relates to a solid-state imaging device and a distance measuring device.

### BACKGROUND

Conventionally, a distance measuring sensor (hereinafter referred to as an iTOF sensor) using an indirect time of flight (TOF) method is known. In the iTOF sensor, a distance to an object is measured based on a signal charge obtained by receiving reflected light of light emitted from a light source at a certain phase.

As a pixel architecture of the iTOF sensor, a dual-tap pixel architecture in which one pixel has two memories is common. In the dual-tap pixel architecture, a distance image indicating a distance to an object is generated based on a ratio of charges accumulated in each of two memories of each pixel.

### CITATION LIST

### Patent Literature

Patent Literature 1: JP 2019-4149 A

### SUMMARY

### Technical Problem

In a general iTOF sensor, an accumulation operation is executed at a modulation frequency of about 100 megahertz (MHz) for all pixels. However, by increasing the modulation frequency, effects such as modulation with interference resistance and improvement in distance measurement accuracy can be obtained. However, increasing the modulation frequency has a problem of increasing power consumption.

Therefore, the present disclosure proposes a solid-state imaging device and a distance measuring device capable of improving distance measurement accuracy while suppressing an increase in power consumption.

### Solution to Problem

To solve the above-described problem, a solid-state imaging device according to one aspect of the present disclosure comprises: a first pixel configured to detect an address event based on incident light; and a second pixel configured to generate information on a distance to an object based on the incident light, wherein the second pixel generates the information on the distance to the object when the first pixel detects the address event.

### BRIEF DESCRIPTION OF DRAWINGS

FIG. 1 is a block diagram illustrating a schematic configuration example of a distance measuring device according to an embodiment of the present disclosure.

FIG. 2 is a diagram illustrating a stacked structure example of a solid-state imaging device according to the embodiment of the present disclosure.

FIG. 3 is a block diagram illustrating a schematic configuration example of the solid-state imaging device according to the embodiment of the present disclosure.

FIG. 4 is a block diagram illustrating a schematic configuration example of a unit pixel according to the embodiment of the present disclosure.

FIG. 5 is a diagram illustrating a stacked structure example in a case where the unit pixel illustrated in FIG. 4 of the present disclosure is applied to a stacked chip illustrated in FIG. 3.

FIG. 6 is a cross-sectional view illustrating a cross-sectional structure example (partial) of a DVS pixel according to the embodiment of the present disclosure.

FIG. 7 is a cross-sectional view illustrating a cross-sectional structure example (partial) of an iTOF pixel according to the embodiment of the present disclosure.

FIG. 8 is a block diagram illustrating a schematic configuration example of the DVS pixel according to the embodiment of the present disclosure.

FIG. 9 is a circuit diagram illustrating a schematic configuration example of a current-voltage conversion unit according to the embodiment of the present disclosure.

FIG. 10 is a circuit diagram illustrating a schematic configuration example of a current-voltage conversion unit according to a modification of the embodiment of the present disclosure.

FIG. 11 is a circuit diagram illustrating a schematic configuration example of a subtractor and a quantizer according to the embodiment of the present disclosure.

FIG. 12 is a circuit diagram illustrating a schematic configuration example of a transfer unit according to the embodiment of the present disclosure.

FIG. 13 is a circuit diagram illustrating an example of an equivalent circuit of an iTOF pixel according to the embodiment of the present disclosure.

FIG. 14 is a circuit diagram illustrating an example of a connection relationship between the DVS pixel and the iTOF pixel in a unit pixel according to the embodiment of the present disclosure.

FIG. 15 is a circuit diagram illustrating a schematic configuration example of an exposure enabler according to the embodiment of the present disclosure.

FIG. 16 is a circuit diagram illustrating a supply configuration example of a read voltage according to the embodiment of the present disclosure.

FIG. 17 is a schematic plan view illustrating a schematic configuration example of a light receiving chip side in the solid-state imaging device according to a first layout example of the embodiment of the present disclosure.

FIG. 18 is a schematic plan view illustrating a schematic configuration example of a circuit chip side in the solid-state imaging device according to the first layout example of an embodiment of the present disclosure.

FIG. 19 is a schematic plan view illustrating a schematic configuration example of the light receiving chip side in the solid-state imaging device according to a second layout example of the embodiment of the present disclosure.

FIG. 20 is a schematic plan view illustrating a schematic configuration example of the circuit chip side in the solid-state imaging device according to the second layout example of the embodiment of the present disclosure.

FIG. 21 is a schematic plan view illustrating a schematic configuration example of the light receiving chip side in the solid-state imaging device according to a third layout example of the embodiment of the present disclosure.

FIG. 22 is a schematic plan view illustrating a schematic configuration example of the circuit chip side in the solid-state imaging device according to the third layout example of the embodiment of the present disclosure.

FIG. 23 is a schematic plan view illustrating a schematic configuration example of the light receiving chip side in the solid-state imaging device according to a fourth layout example of the embodiment of the present disclosure.

FIG. 24 is a schematic plan view illustrating a schematic configuration example of the circuit chip side in the solid-state imaging device according to the fourth layout example of the embodiment of the present disclosure.

FIG. 25 is a block diagram illustrating a partial schematic configuration example of the iTOF pixel in the unit pixel according to the fourth layout example of the embodiment of the present disclosure.

FIG. 26 is a block diagram illustrating a partial schematic configuration example of the unit pixel according to the fourth layout example of the embodiment of the present disclosure.

FIG. 27 is a diagram illustrating a schematic operation example of the solid-state imaging device according to the embodiment of the present disclosure.

FIG. 28 is a diagram illustrating a first modification of the solid-state imaging device according to the embodiment of the present disclosure.

FIG. 29 is a diagram illustrating a second modification of the solid-state imaging device according to the embodiment of the present disclosure.

FIG. 30 is a flowchart illustrating a schematic operation example of the solid-state imaging device according to the embodiment of the present disclosure.

FIG. 31 is a flowchart schematically illustrating a distance image generation operation according to a first example of the embodiment of the present disclosure.

FIG. 32 is a block diagram illustrating a schematic configuration of the solid-state imaging device according to a second example of the embodiment of the present disclosure.

FIG. 33 is a flowchart schematically illustrating the distance image generation operation according to the second example of the embodiment of the present disclosure.

FIG. 34 is a schematic diagram illustrating a principle of calculating a distance to a long-distance object based on movement of the distance measuring device according to the embodiment of the present disclosure and movement of an image of the long-distance object.

FIG. 35 is a block diagram illustrating a schematic configuration example of a measure against flicker according to the embodiment of the present disclosure.

FIG. 36 is a block diagram illustrating a schematic configuration example of a vehicle control system.

FIG. 37 is an explanatory diagram illustrating an example of installation positions of a vehicle exterior information detection unit and an imaging unit.

### DESCRIPTION OF EMBODIMENTS

Hereinafter, an embodiment of the present disclosure will be described with reference to the drawings. In the following embodiments, same parts are given the same reference signs to omit redundant description.

The present disclosure will be described according to the following item order.

1. Embodiment

1.1 Configuration example of distance measuring device

1.2 Stacked structure example of solid-state imaging device

1.3 Schematic configuration example of solid-state imaging device

1.4 Schematic configuration example of unit pixel

1.4.1 Stacked structure example of unit pixels

1.4.2 Cross-sectional structure example of unit pixel

1.4.2.1 Cross-sectional structure example of DVS pixel

1.4.2.2 Cross-sectional structure example of iTOF pixel

1.5 Schematic configuration example of DVS pixel

1.5.1 Function example of address event detection circuit

1.5.2 Configuration example of address event detection circuit

1.5.2.1 Configuration example of current-voltage conversion unit

1.5.2.1.1 Modification of current-voltage conversion unit

1.5.3 Configuration example of subtractor and quantizer

1.5.4 Configuration example of transfer unit

1.6 Schematic configuration example of iTOF pixel

1.7 Drive control of iTOF pixel triggered by detection of address event

1.7.1 Example of connection relationship between DVS pixel and iTOF pixel in unit pixel

1.7.2 Schematic configuration example of exposure enabler

1.7.3 Supply configuration example of read voltage

1.8 Layout example of solid-state imaging device

1.8.1 First layout example

1.8.2 Second layout example

1.8.3 Third layout example

1.8.4 Fourth layout example

1.9 Schematic operation example of solid-state imaging device

1.9.1 First modification

1.9.2 Second modification

1.10 Flowchart of schematic operation example

1.11 Example of distance image generation operation

1.11.1 First example

1.11.2 Second example

1.11.3 Calculation method of distance to long-distance object based on movement of distance measuring device and movement of image of long-distance object

1.12 Measure against flickers

1.13 Summary

2. Application to mobile body

### 1. EMBODIMENT

First, a solid-state imaging device and a distance measuring device according to an embodiment of the present disclosure will be described in detail below with reference to the drawings.

1.1 Configuration Example of Distance Measuring Device

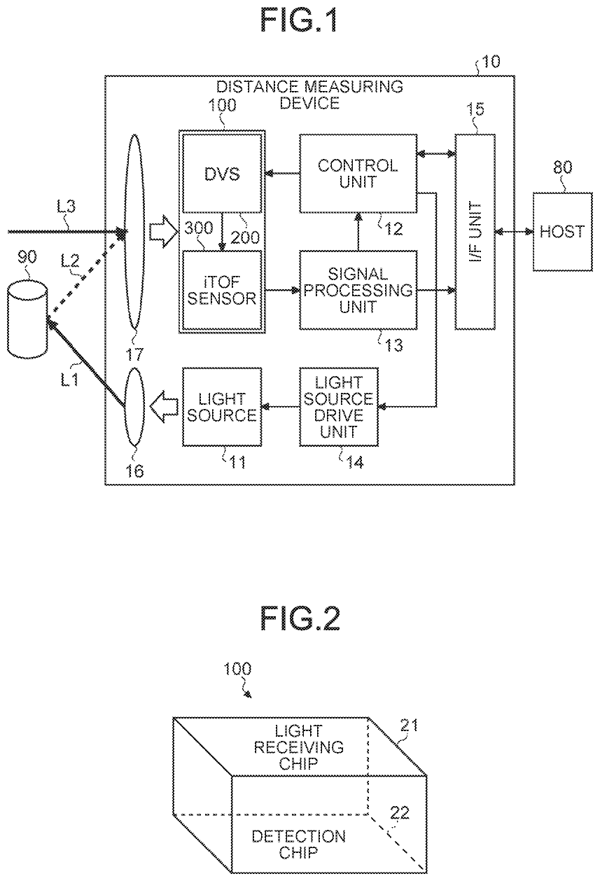

FIG. 1 is a block diagram illustrating a schematic configuration example of the distance measuring device according to the embodiment of the present disclosure. As illustrated in FIG. 1, a distance measuring device 10 includes a solid-state imaging device 100, a light source 11, a control unit 12, a signal processing unit 13, a light source drive unit 14, an interface (I/F) unit 15, and optical systems 16 and 17, and is connected to a host 80 on a predetermined network via the I/F unit 15. The predetermined network may be various networks including a bus network such as a universal serial bus (USB), a communication network conforming to an arbitrary standard such as a controller area network (CAN), a local interconnect network (LIN), and FlexRay (registered trademark) in addition to a wireless local area network (LAN) and a wired LAN. In this case, the I/F unit 15 may be a communication adapter or the like conforming to these network standards.

For example, when the distance measuring device 10 is mounted on an automobile, the host 80 may be an engine control unit (ECU) mounted on the automobile. Furthermore, in a case where the distance measuring device 10 is mounted on an autonomous mobile robot such as a domestic pet robot or an autonomous mobile body such as a robot cleaner, an unmanned aerial vehicle, or a following conveyance robot, the host 80 may be a control device that controls the autonomous mobile body. In addition, the host 80 may be, for example, an information processing apparatus such as a personal computer.

The control unit 12 includes a processor such as a central processing unit (CPU), for example, and controls each unit of the distance measuring device 10. For example, the control unit 12 executes signal reading control on the solid-state imaging device 100, and gives an instruction such as timing of outputting laser light L1 from the light source 11 and intensity of the laser light L1 to be output to the light source drive unit 14.

The light source drive unit 14 drives the light source 11 in accordance with the instruction from the control unit 12. The light source 11 includes, for example, one or a plurality of semiconductor laser diodes, and emits a pulsed laser light L1 having a predetermined time width at a predetermined cycle (also referred to as a light emission cycle) by driving of the light source drive unit 14. For example, the light source 11 may emit the laser light L1 toward an angle range equal to or larger than an angle of view of the solid-state imaging device 100. In addition, the light source 11 emits, for example, the laser light L1 having a time width of 0.5 nanoseconds (ns) at a cycle of 1 gigahertz (GHz). A beam profile of the laser light L1 emitted from the light source 11 is adjusted through the optical system 16, and the laser light L1 is output from the distance measuring device 10. For example, in a case where an object 90 exists within a distance measurement range, the laser light L1 output from the distance measuring device 10 is reflected by this object 90 and enters the solid-state imaging device 100 as reflected light L2 via the optical system 17 that is a condensing optical system and/or an imaging optical system. Note that not only the reflected light L2 but also normal light L3 enters the solid-state imaging device 100.

Although details will be described later, the solid-state imaging device 100 has a configuration in which, for example, a dynamic vision sensor (DVS) 200 and an iTOF sensor 300 are built in a single semiconductor chip.

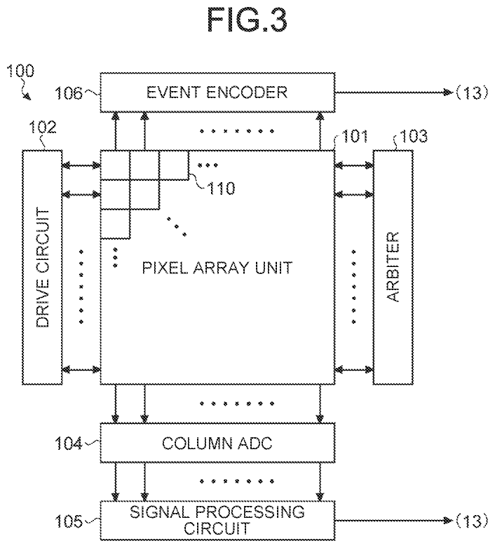

The signal processing unit 13 executes a predetermined process on signal data input from the solid-state imaging device 100. For example, the signal processing unit 13 generates image data based on an address signal input within a predetermined period from the DVS 200 in the solid-state imaging device 100. Furthermore, the signal processing unit 13 generates a distance image based on distance information for each address input from the iTOF sensor 300 in the solid-state imaging device 100. Note that the address in the present description may be an address in an X-Y coordinate system corresponding to a position on a pixel array unit 101 (see FIG. 3) of each unit pixel 110 (also see FIG. 3) described later.

For example, the image data and the distance image generated by the signal processing unit 13 may be input to the control unit 12, may be transmitted to the host 80 outside via an I/F unit 150, or may be stored in a storage unit (not illustrated).

1.2 Stacked Structure Example of Solid-State Imaging Device

FIG. 2 is a diagram illustrating a stacked structure example of the solid-state imaging device according to the present embodiment. As illustrated in FIG. 2, the solid-state imaging device 100 has a stacked chip structure in which a light receiving chip 21 and a circuit chip 22 are vertically stacked. For bonding the light receiving chip 21 and the circuit chip 22, for example, so-called direct bonding can be used in which the bonding surfaces are flattened and the bonding surfaces are bonded to each other by an intermolecular force. However, the present invention is not limited thereto, and for example, so-called Cu—Cu bonding in which copper (Cu) electrode pads formed on bonding surfaces are bonded to each other, bump bonding, or the like can also be used.

In addition, for example, the light receiving chip 21 and the circuit chip 22 are electrically connected via a connecting portion such as a through-silicon via (TSV) penetrating a semiconductor substrate. For the connection using the TSV, for example, a so-called twin TSV method in which two TSVs, i.e., a TSV provided in the light receiving chip 21 and a TSV provided from the light receiving chip 21 to the circuit chip 22, are connected on an outer surface of the chip, or a so-called shared TSV method in which the light receiving chip 21 and the circuit chip 22 are connected by a TSV penetrating from the light receiving chip 21 to the circuit chip 22 can be adopted.

However, when Cu—Cu bonding or bump bonding is used for bonding the light receiving chip 21 and the circuit chip 22, both are electrically connected via a Cu—Cu bonded portion or a bump bonded portion.

1.3 Schematic Configuration Example of Solid-State Imaging Device

FIG. 3 is a block diagram illustrating a schematic configuration example of the solid-state imaging device according to the present embodiment. As illustrated in FIG. 3, the solid-state imaging device 100 includes a pixel array unit 101, a drive circuit 102, an arbiter 103, a column ADC (converter) 104, a signal processing circuit 105, and an event encoder 106.

The pixel array unit 101 has a configuration in which a plurality of unit pixels 110 is arranged in a two-dimensional lattice pattern (also referred to as a matrix pattern). Hereinafter, a group of the unit pixels 110 aligned in the horizontal direction is referred to as a “row”, and a group of the unit pixels 110 aligned in a direction perpendicular to the row is referred to as a “column”. A position of each unit pixel 110 in the row direction in the pixel array unit 101 is specified by an X address, and a position in the column direction is specified by a Y address.

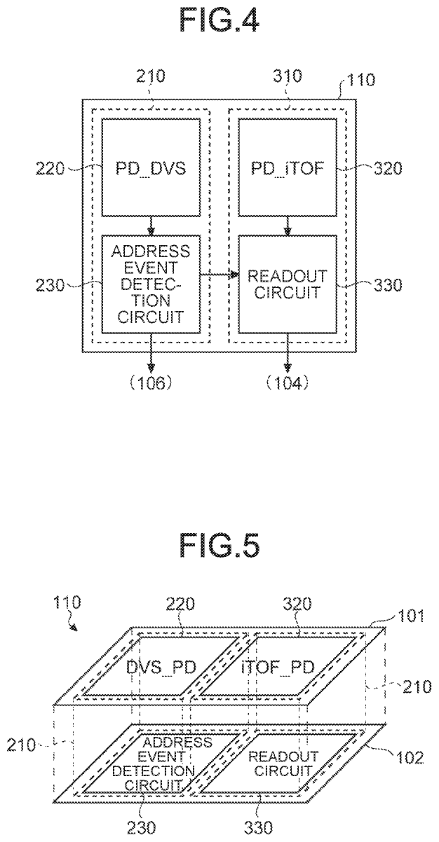

Each unit pixel 110 includes one or more DVS pixels 210 (e.g., FIG. 4) and one or more iTOF pixels 310 (also FIG. 4), as described later. The configuration and operation of each of the DVS pixel 210 and the iTOF pixel 310 will be described later.

The unit pixel 110 in which an address event is detected in the DVS pixel 210 outputs a request to the arbiter 103. Furthermore, when receiving a response to the request from the arbiter, the unit pixel 110 transmits a detection signal indicating a detection result of the address event to the drive circuit 102, a column ADC 104, and the iTOF pixel 310.

The arbiter 103 arbitrates a request from one or more unit pixels 110 to determine a readout order of the unit pixels 110 that are a transmission source of the request, and returns a response to the unit pixels 110 that have transmitted the request based on the determined readout order. Note that, in the following description, arbitrating the request to determine the readout order is referred to as “arbitrating the readout order”.

The drive circuit 102 drives the iTOF pixel 310 belonging to the unit pixel 110 that has output the detection signal, thereby causing a pixel signal generated by the iTOF pixel 310 of each unit pixel 110 to appear in a vertical signal line (VSL) 403 to be described later. Note that this pixel signal corresponds to depth information indicating a distance to a subject (object 90, etc.) indicated by light incident (reflected light L2, etc.) on the unit pixel 110.

For each row, the column ADC 104 converts an analog pixel signal appearing in the vertical signal line (VSL) 403 of each column into a digital pixel signal, thereby reading out the pixel signals in column parallel. Then, the column ADC 104 supplies the digital pixel signal read to the signal processing circuit 105.

The signal processing circuit 105 performs a predetermined signal process such as a correlated double sampling (CDS) process on the pixel signal from the column ADC 104, and outputs the depth information including the pixel signal after the signal process to, for example, the external signal processing unit 13.

The event encoder 106 generates data indicating the unit pixel 110 where on-event has occurred and the unit pixel 110 where an off-event has occurred in the pixel array unit 101. For example, when receiving a request from a certain unit pixel 110, the event encoder 106 generates event detection data including occurrence of the on-event or the off-event in this unit pixel 110 and an X address and a Y address indicating the position of the unit pixel 110 in the pixel array unit 101.

In this case, the event encoder 106 also includes, in the event detection data, information regarding the time when the on-event or the off-event is detected (time stamp). Note that the generated event detection data may be output to the external signal processing unit 13 and used for generation of image data in the signal processing unit 13.

1.4 Schematic Configuration Example of Unit Pixel

FIG. 4 is a block diagram illustrating a schematic configuration example of the unit pixel according to the present embodiment. As illustrated in FIG. 4, each unit pixel 110 includes one or more DVS pixels 210 for detecting address events and one or more iTOF pixels 310 for obtaining the distance information to an object.

Each of the DVS pixels 210 includes a photodiode (hereinafter also referred to as PD_DVS) 220 as a photoelectric conversion unit that generates a photocurrent according to an amount of incident light, and an address event detection circuit (hereinafter also referred to as analog-front-end (AFE)_DVS) 230 that detects the address event based on a photocurrent from the PD_DVS 220.

Each iTOF pixel 310 includes a photodiode (hereinafter also referred to as PD_iTOF) 320 as the photoelectric conversion unit that generates the photocurrent according to the amount of incident light, and a readout circuit 330 that generates a pixel signal indicating the distance information to the object based on the photocurrent from the PD_iTOF 320.

The present embodiment exemplifies a case where the iTOF sensor 300 is a current assisted photonic demodulator (CAPD) type iToF sensor capable of modulating a wide region in a substrate at a high speed by directly applying a voltage to the semiconductor substrate and generating a current in the substrate. However, the present invention is not limited thereto, and various iTOF sensors can be used as the iTOF sensor 300.

1.4.1 Stacked Structure Example of Unit Pixels

FIG. 5 is a diagram illustrating a stacked structure example in a case where the unit pixels illustrated in FIG. 4 are applied to stacked chips illustrated in FIG. 3. As illustrated in FIG. 5, among the unit pixels 110, for example, the DVS pixel 210 and the iTOF pixel 310 are arranged on the light receiving chip 21, and the address event detection circuit 230 and the readout circuit 330 are arranged on the circuit chip 22.

However, the present disclosure is not limited thereto, and various modifications can be made. For example, some or all of the circuit configurations in the address event detection circuit 230 and the readout circuit 330 may be arranged on the light receiving chip 21.

1.4.2 Cross-Sectional Structure Example of Unit Pixel

Next, a cross-sectional structure example of the unit pixel 110 according to the present embodiment will be described. Note that, as described above, one unit pixel 110 may include one or more DVS pixels 210 and one or more iTOF pixels 310. Therefore, in the present description, the cross-sectional structure example of the DVS pixel 210 and the cross-sectional structure of the iToF pixel 310 will be separately described. The following description will mainly focus on the cross-sectional structures of the DVS pixel 210 and iToF pixel 310 on the side of the light receiving chip 21.

1.4.2.1 Cross-Sectional Structure Example of DVS Pixel

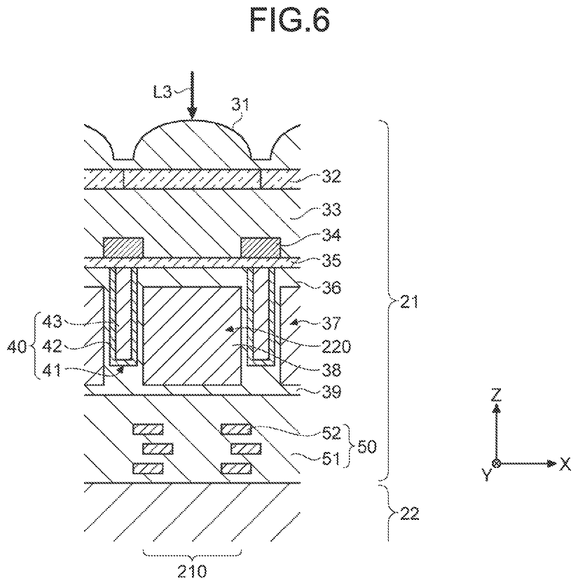

FIG. 6 is a cross-sectional view illustrating the cross-sectional structure example (partial) of the DVS pixel according to the present embodiment. As illustrated in FIG. 6, in the DVS pixel 210, the photodiode 220 receives light L3 (including reflected light L2, hereinafter referred to as incident light L3) entering from a rear surface (upper surface in FIG. 6) of a semiconductor substrate 37. Above the photodiode 220, a planarization film 33, a color filter 32, and a microlens 31 are provided. As the semiconductor substrate 37, a silicon substrate including a p-well may be used. A substrate thickness is reduced to, for example, a thickness of 20 micrometers (μm) or less. Note that the thickness of the semiconductor substrate 37 may be 20 μm or more, and the thickness may be appropriately determined according to target characteristics or the like of the solid-state imaging device 100.

For example, in the photodiode 220, an N-type semiconductor region 38 is formed as a charge accumulation region that accumulates charges (electrons). In the photodiode 220, the N-type semiconductor region 38 is provided in a region surrounded by P-type semiconductor regions 36 and 39 of the semiconductor substrate 37. The P-type semiconductor region 39 having a higher impurity concentration than that of the rear surface (upper surface) side is provided on the front surface (lower surface) side of the N-type semiconductor region 38 in the semiconductor substrate 37. In other words, the photodiode 220 has a hole-accumulation diode (HAD) structure, and the P-type semiconductor regions 36 and 39 are formed so as to suppress generation of a dark current at each interface between the upper surface side and the lower surface side of the N-type semiconductor region 38.

Pixel isolation parts 40 that electrically isolate a plurality of pixels from each other are provided inside the semiconductor substrate 37, and the photodiode 220 is provided in a region partitioned by these pixel isolation parts 40. In the drawing, in a case where the DVS pixel 210 is viewed from the upper surface side, the pixel isolation parts 40 are formed in, for example, a lattice shape so as to be interposed between a plurality of pixels, and the photodiode 220 is formed in a region partitioned by these pixel isolation parts 40.

An anode of each photodiode 220 is grounded, and the signal charge (e.g., electron) accumulated by the photodiode 220 in the DVS pixel 210 is output to the address event detection circuit 230 (not illustrated).

A wiring layer 50 is provided on the front surface (lower surface) side of the semiconductor substrate 37 opposite to the rear surface (upper surface) side on which respective parts such as a light shielding part 34 and the microlens 31 are provided.

The wiring layer 50 includes a wiring 52 and an insulating layer 51, and is formed in the insulating layer 51 such that the wiring 52 is electrically connected to each element. The wiring layer 50 is a so-called multilayer wiring layer, and is formed by alternately stacking an interlayer insulating film configuring the insulating layer 51 and the wiring 52 a plurality of times. Here, the wiring 52 may include a wiring for connecting a cathode of the photodiode 220 to a source of an LG transistor 411, a gate of an amplification transistor 413, and the like to be described later.

For example, the circuit chip 22 in which peripheral circuits such as the address event detection circuit 230, the readout circuit 330, the drive circuit 102, the arbiter 103, the column ADC 104, the signal processing circuit 105, and the event encoder 106 are incorporated can be bonded to a surface of the wiring layer 50 on the opposite side of a side on which the photodiode 220 is provided.

The light shielding part 34 is provided on the rear surface (upper surface in the drawing) side of the semiconductor substrate 37.

The light shielding part 34 is configured to shield a part of the incident light L3 from above the semiconductor substrate 37 toward the rear surface of the semiconductor substrate 37.

The light shielding part 34 is provided above the pixel isolation part 40 provided inside the semiconductor substrate 37. Here, the light shielding part 34 is provided so as to protrude in a convex shape via an insulating film 35, such as a silicon oxide film, functioning as an antireflection film on the rear surface (upper surface) of the semiconductor substrate 37. On the other hand, the light shielding part 34 is not provided above the photodiode 220 provided inside the semiconductor substrate 37 and is open so that the incident light L3 enters the photodiode 220.

In other words, in the drawing, when the DVS pixel 210 is viewed from the upper surface side, a planar shape of the light shielding part 34 is a lattice shape, and the opening through which the incident light L3 passes to the light receiving surface 137 is created.

The light shielding part 34 is formed of a light shielding material that blocks light. For example, the light shielding part 34 is formed by sequentially stacking a titanium (Ti) film and a tungsten (W) film. In addition, the light shielding part 34 can be formed, for example, by sequentially stacking a titanium nitride (TiN) film and the tungsten (W) film.

The light shielding part 34 is covered with the planarization film 33. The planarization film 33 is formed using an insulating material that transmits light. As the insulating material, for example, silicon oxide (SiO2) can be used.

The pixel isolation part 40 includes, for example, a groove 41, a fixed charge film 42, and an insulating film 43.

The fixed charge film 42 is formed on the rear surface (upper surface) side of the semiconductor substrate 37 so as to cover the groove 41 defining the plurality of pixels.

Specifically, the fixed charge film 42 is provided so as to cover the inner surface of the groove 41 formed on the rear surface (upper surface) side of the semiconductor substrate 37 with a constant thickness. Then, the insulating film 43 is provided (injected) so as to fill the inside of the groove 41 covered with the fixed charge film 42.

Here, the fixed charge film 42 is formed using a high dielectric having a negative fixed charge so that a positive charge (hole) accumulation region is formed at an interface portion with the semiconductor substrate 37 to suppress generation of the dark current. Since the fixed charge film 42 is formed to have the negative fixed charge, an electric field is applied to the interface with the semiconductor substrate 37 by the negative fixed charge, and the positive charge (hole) accumulation region is formed.

The fixed charge film 42 can be formed of, for example, a hafnium oxide film (HfO2 film). In addition, the fixed charge film 42 can be formed to contain, for example, at least one of oxides such as hafnium, zirconium, aluminum, tantalum, titanium, magnesium, yttrium, and lanthanoid elements.

Note that the pixel isolation part 40 is not limited to the above configuration, and can be variously modified. For example, by using a reflection film that reflects light, such as a tungsten (W) film, instead of the insulating film 43, the pixel isolation part 40 can have a light reflection structure. As a result, the incident light L3 entering the photodiode 220 can be reflected by the pixel isolation part 40, so that the optical path length of the incident light L3 in the photodiode 220 can be increased. In addition, since the pixel isolation part 40 has the light reflection structure, it is possible to reduce leakage of light to adjacent pixels, and thus, it is also possible to further improve image quality, distance measurement accuracy, and the like. Note that, in a case where a metal material such as tungsten (W) is used as the material of the reflection film, an insulating film such as a silicon oxide film may be provided in the groove 41 instead of the fixed charge film 42.

Furthermore, the configuration in which the pixel isolation part 40 has the light reflection structure is not limited to the configuration using the reflection film, and can be realized, for example, by embedding in the groove 41 a material having a higher refractive index or a lower refractive index than the semiconductor substrate 37.

Furthermore, FIG. 6 illustrates the pixel isolation part 40 having a so-called reverse deep trench isolation (RDTI) structure in which the pixel isolation part 40 is provided in the groove 41 formed from the rear surface (upper surface) side of the semiconductor substrate 37, but the present invention is not limited thereto. For example, the pixel isolation part 40 having various structures such as a so-called deep trench isolation (DTI) structure in which the pixel isolation part 40 is provided in the groove portion formed from the front surface (lower surface) side of the semiconductor substrate 37 and a so-called full trench isolation (FTI) structure in which the pixel isolation part 40 is provided in the groove formed so as to penetrate the front and rear surfaces of the semiconductor substrate 37 can be adopted.

Furthermore, an uneven structure for suppressing reflection of the incident light L3 or generating diffraction of the incident light L3 may be provided at the interface between the insulating film 35 and the semiconductor substrate 37 configuring the light receiving surface of each pixel.

1.4.2.2 Cross-Sectional Structure Example of iTOF Pixel

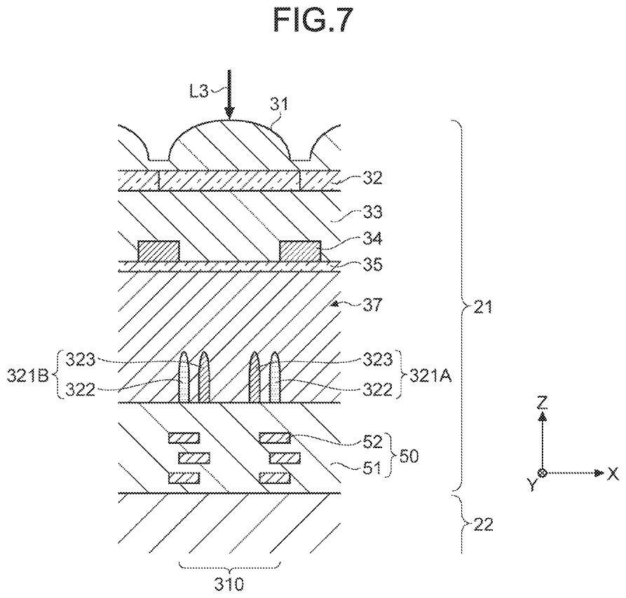

FIG. 7 is a cross-sectional view illustrating a cross-sectional structure example (partial) of the iTOF pixel according to the present embodiment. As illustrated in FIG. 7, in the iTOF pixel 310, in the cross-sectional structure similar to that of the DVS pixel 210 illustrated in FIG. 6, a configuration built in the semiconductor substrate 37 having the p-well structure is replaced with a pair of signal extraction units 321A and 321B. The signal extraction units 321A and 321B may be provided on the front surface side (lower surface side in the drawing) of the semiconductor substrate 37.

Here, a MIX 322 in each of the signal extraction units 321A and 321B may be, for example, a region in which an acceptor such as boron (B) is diffused in the semiconductor substrate 37, and a DET 323 may be a region in which a donor such as phosphorus (P) or arsenic (As) is diffused in the semiconductor substrate 37.

The DET 323 of each of the signal extraction units 321A and 321B functions as a charge detection unit for detecting an amount of light incident on the photodiode (PD_iTOF) 320 from the outside, i.e., an amount of charge generated by photoelectric conversion by the semiconductor substrate 37.

On the other hand, the MIX 322 functions as a voltage application unit for injecting a majority carrier current into the semiconductor substrate 37, i.e., for applying a voltage directly to the semiconductor substrate 37 to generate an electric field in the semiconductor substrate 37.

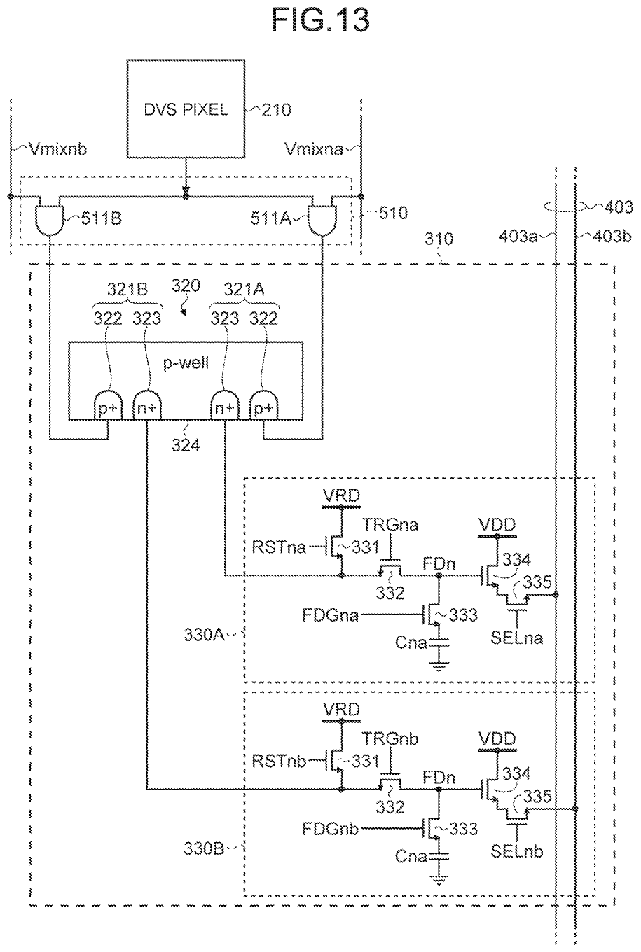

In the present embodiment, for example, a floating diffusion region FDn of the readout circuit 330A or 330B described later is directly connected to the DET 323 of the signal extraction unit 321A or 321B (e.g., FIG. 13).

Note that, although not illustrated in FIG. 7, similarly to the DVS pixel 210, for example, the semiconductor substrate 37 may be provided with the pixel isolation part 40 in a lattice pattern for optically isolating the individual photodiodes 320.

1.5 Schematic Configuration Example of DVS Pixel

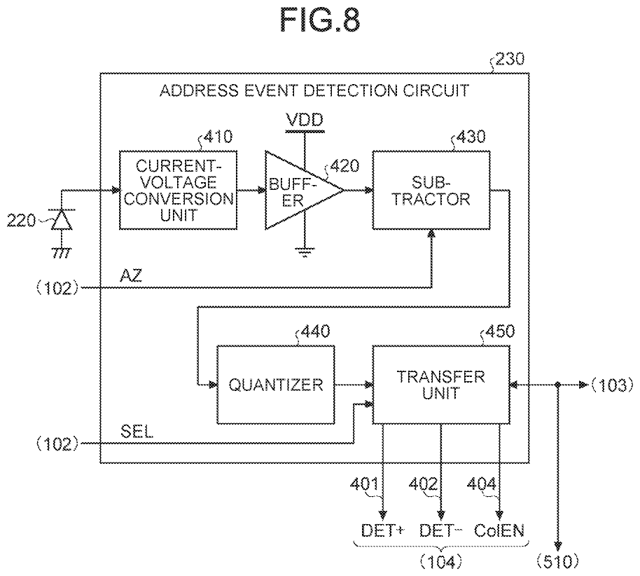

Next, a schematic configuration example of the DVS pixel according to the present embodiment will be described. FIG. 8 is a block diagram illustrating the schematic configuration example of the DVS pixel according to the present embodiment.

1.5.1 Function Example of Address Event Detection Circuit

The address event detection circuit 230 illustrated in FIG. 8 detects an address event based on whether or not a change amount of the photocurrent flowing out of the photodiode (PD_DVS) 220 exceeds a predetermined threshold. The address event includes, for example, an on-event indicating that the change amount of the photocurrent according to an incident light amount exceeds an upper limit threshold and an off-event indicating that the change amount falls below a lower limit threshold. In other words, the address event is detected when the change amount of the incident light is out of the predetermined range from the lower limit to the upper limit.

A detection signal indicating a detection result of the address event may include, for example, one bit indicating an on-event detection result and one bit indicating an off-event detection result. Note that the address event detection circuit 230 may be configured to detect only the on-event or the off-event.

When the address event occurs, the address event detection circuit 230 transmits a request for transmission of the detection signal to the arbiter 103. Then, upon receiving a response to the request from the arbiter 103, the address event detection circuit 230 transmits detection signals DET+ and DET− to the drive circuit 102 and the column ADC 104. Here, the detection signal DET+ is a signal indicating the detection result of the presence or absence of the on-event, and is transmitted to the column ADC 104 via, for example, a detection signal line 401. In addition, the detection signal DET− is a signal indicating the detection result of the presence or absence of the off-event, and is transmitted to the column ADC 104 via, for example, a detection signal line 402.

Note that the request output from the address event detection circuit 230 to the arbiter 103 is also input to an exposure enabler 510 including two AND circuits 511A and 511B connected to the iTOF pixel 310. The exposure enabler 510 may be all or a part of an exposure control unit in claims. As will be described later, since the request is a logical sum of COMP+ and COMP− that are comparison results of a quantizer 440, read voltages Vmixna and Vmixnb are input to the iTOF pixel 310 only when the on-event or the off-event is detected, i.e., only when the detection signal DET+ or DET− is ‘1’ indicating detection of the address event.

In addition, the address event detection circuit 230 sets a column enable signal ColEN to an enable state in synchronization with a selection signal SEL for selecting the unit pixel 110 to be read, and transmits the signal to the column ADC 104 via an enable signal line 404. Here, the column enable signal ColEN is a signal for enabling or disabling analog to digital (AD) conversion of the pixel signal in a corresponding column.

In addition, the unit pixel 110 that has detected the address event in a driven row transmits the column enable signal ColEN set in the enable state to the column ADC 104. On the other hand, the column enable signal ColEN of the unit pixel 110 in which the address event has not been detected is set to a disable state.

1.5.2 Configuration Example of Address Event Detection Circuit

As illustrated in FIG. 8, the address event detection circuit 230 includes a current-voltage conversion unit 410, a buffer 420, a subtractor 430, a quantizer 440, and a transfer unit 450.

The current-voltage conversion unit 410 converts the photocurrent from the DVS pixel 210 into a logarithmic voltage signal. Then, the current-voltage conversion unit 410 supplies the voltage signal to the buffer 420.

The buffer 420 outputs the voltage signal from the current-voltage conversion unit 410 to the subtractor 430. This buffer 420 can improve the driving force for driving a subsequent stage. In addition, the buffer 420 can ensure noise isolation associated with a switching operation in the subsequent stage.

The subtractor 430 reduces a level of the voltage signal from the buffer 420 according to a row drive signal from the drive circuit 102. Then, the subtractor 430 supplies a reduced voltage signal to the quantizer 440.

The quantizer 440 quantizes the voltage signal from the subtractor 430 into a digital signal and outputs the digital signal to the transfer unit 450 as a detection signal.

The transfer unit 450 transfers the detection signal from the quantizer 440 to the signal processing circuit 105 and the like. When the address event is detected, the transfer unit 450 transmits a request for transmission of the detection signal to the arbiter 103 and the event encoder 106. Then, upon receiving a response to the request from the arbiter 103, the transfer unit 450 supplies the detection signals DET+ and DET− to the drive circuit 102 and the column ADC 104. When the selection signal SEL is transmitted, the transfer unit 450 transmits the column enable signal ColEN set in the enable state to the column ADC 104.

1.5.2.1 Configuration Example of Current-Voltage Conversion Unit

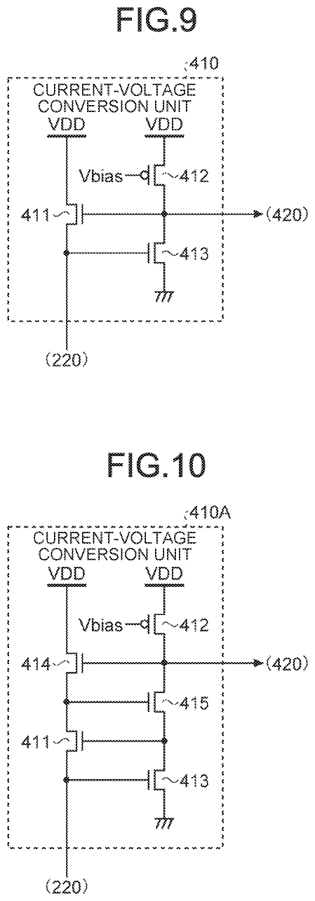

FIG. 9 is a circuit diagram illustrating a schematic configuration example of the current-voltage conversion unit according to the present embodiment. As illustrated in FIG. 9, the current-voltage conversion unit 410 includes an LG (LoG) transistor 411, an amplification transistor 413, and a load MOS transistor 412. For example, an N-type MOS transistor can be used for the LG transistor 411 and the amplification transistor 413. On the other hand, the load MOS transistor 412 is a constant current circuit, and a P-type MOS transistor can be used for the load MOS transistor 412.

A source of the LG transistor 411 is connected to a cathode of the photodiode (PD_DVS) 220 in the DVS pixel 210, and a drain thereof is connected to a power supply terminal. The load MOS transistor 412 and the amplification transistor 413 are connected in series between the power supply terminal and a ground terminal. Furthermore, a connection point of the load MOS transistor 412 and the amplification transistor 413 is connected to the gate of the LG transistor 411 and an input terminal of the buffer 420. In addition, a predetermined bias voltage Vbias is applied to the gate of the load MOS transistor 412.

Drains of the LG transistor 411 and the amplification transistor 413 are connected to the power supply side, and this type of circuit is called a source follower. The photocurrent from the photodiode (PD_DVS) 220 is converted into the logarithmic voltage signal by two source followers connected in a loop shape. Furthermore, the load MOS transistor 412 supplies a constant current to the amplification transistor 413.

Note that, in the configuration illustrated in FIG. 9, for example, the LG transistor 411 and the amplification transistor 413 may be arranged on the light receiving chip 21 illustrated in FIG. 5.

1.5.2.1.1 Modification of Current-Voltage Conversion Unit

Instead of the source follower type current-voltage conversion unit 410 illustrated in FIG. 9, a gain boost type current-voltage conversion unit 410A illustrated in FIG. 10 can be used.

As illustrated in FIG. 10, in the current-voltage conversion unit 410A, the source of the LG transistor 411 and the gate of the amplification transistor 413 are connected to, for example, the cathode of the photodiode (PD_DVS) 220 in the DVS pixel 210. Furthermore, the drain of the LG transistor 411 is connected to, for example, the source of an LG transistor 414 and the gate of the amplification transistor 413. For example, the drain of the LG transistor 414 is connected to the power supply terminal VDD.

Furthermore, for example, the source of an amplification transistor 415 is connected to the gate of the LG transistor 411 and the drain of the amplification transistor 413. The drain of the amplification transistor 415 is connected, for example, to the power supply terminal VDD via the load MOS transistor 412.

Even in such a configuration, the photocurrent from the photodiode (PD_DVS) 220 is converted into the logarithmic voltage signal corresponding to the charge amount. Note that each of the LG transistors 411 and 414 and the amplification transistors 413 and 415 may include, for example, the N-type MOS transistor.

Note that, in the configuration illustrated in FIG. 10, for example, the LG transistors 411 and 414 and the amplification transistors 413 and 415 may be arranged on the light receiving chip 21 illustrated in FIG. 5.

1.5.3 Configuration Example of Subtractor and Quantizer

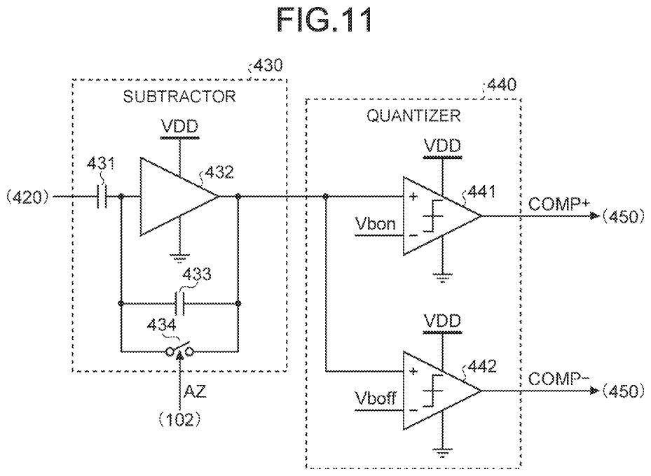

FIG. 11 is a circuit diagram illustrating a schematic configuration example of the subtractor and the quantizer according to the present embodiment. As illustrated in FIG. 11, the subtractor 430 includes capacitors 431 and 433, an inverter 432, and a switch 434. Furthermore, the quantizer 440 includes comparators 441 and 442.

One end of the capacitor 431 is connected to an output terminal of the buffer 420, and the other end is connected to an input terminal of the inverter 432. The capacitor 433 is connected in parallel to the inverter 432. The switch 434 opens and closes a path connecting both ends of the capacitor 433 according to an auto-zero signal AZ from the drive circuit 102.

The inverter 432 inverts the voltage signal input via the capacitor 431. The inverter 432 outputs the inverted signal to a non-inverting input terminal (+) of the comparator 441.

When the switch 434 is turned on, the voltage signal Vinit is input to the buffer 420 side of the capacitor 431, and the opposite side becomes a virtual ground terminal. A potential of the virtual ground terminal is set to zero for convenience. Here, a potential Qinit accumulated in the capacitor 431 is expressed by Expression (1) below when the capacitor 431 has capacitance C1. On the other hand, since both ends of the capacitor 433 are short-circuited, the accumulated charge becomes 0.

Qinit=C1×Vinit (1)

Next, considering a case where the switch 434 is turned off and the voltage on the buffer 420 side of the capacitor 431 changes to Vafter, a charge Qafter accumulated in the capacitor 431 is expressed by Expression (2) below.

Qafter=C1×Vafter (2)

On the other hand, when the output voltage is Vout, a charge Q2 accumulated in the capacitor 433 is expressed by Expression (3) below.

Q2=−C2×Vout (3)

Here, since the total charge amount of the capacitors 431 and 433 does not change, Expression (4) below is established.

Qinit=Qafter+Q2 (4)

When Expressions (1) to (3) are substituted into Expression (4) and deformed, Expression (5) below is obtained.

Vout=−(C1/C2)×(Vafter−Vinit) (5)

Expression (5) represents the subtraction operation of the voltage signal, and the gain of the subtraction result is C1/C2. Since it is usually desired to maximize the gain, it is preferable to design C1 to be large and C2 to be small. On the other hand, when C2 is too small, kTC noise increases, and noise characteristics may deteriorate. Therefore, capacity reduction of C2 is limited to a range in which noise can be tolerated. Furthermore, since the address event detection circuit 230 including the subtractor 430 is mounted for each unit pixel 110, the capacitances C1 and C2 have area restrictions. In consideration of these, the values of the capacitances C1 and C2 are determined.

The comparator 441 compares the voltage signal from the subtractor 430 with an upper limit voltage Vbon applied to an inverting input terminal (−). Here, the upper limit voltage Vbon is a voltage indicating the upper limit threshold. The comparator 441 outputs a comparison result COMP+ to the transfer unit 450. The comparator 441 outputs a high-level comparison result COMP+ when the on-event occurs, and outputs a low-level comparison result COMP+ when there is no on-event.

The comparator 442 compares the voltage signal from the subtractor 430 with a lower limit voltage Vboff applied to the inverting input terminal (−). Here, the lower limit voltage Vboff is a voltage indicating the lower limit threshold. The comparator 442 outputs the comparison result COMP- to the transfer unit 450. The comparator 442 outputs a high-level comparison result COMP− when the off-event occurs, and outputs a low-level comparison result COMP− when there is no off-event.

1.5.4 Configuration Example of Transfer Unit

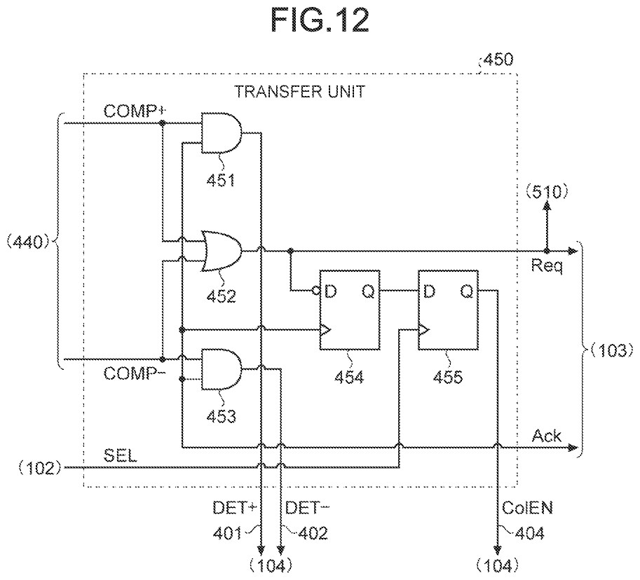

FIG. 12 is a circuit diagram illustrating a schematic configuration example of the transfer unit according to the present embodiment. As illustrated in FIG. 12, the transfer unit 450 includes AND (logical product) gates 451 and 453, an OR (logical sum) gate 452, and flip-flops 454 and 455.

The AND gate 451 outputs the logical product of the comparison result COMP+ of the quantizer 440 and a response Ack from the arbiter 103 to the column ADC 104 as the detection signal DET+. The AND gate 451 outputs the high-level (e.g., ‘1’) detection signal DET+ in a case where the on-event occurs, and outputs the low-level (e.g., ‘0’) detection signal DET+ in a case where there is no on-event.

The OR gate 452 outputs the logical sum of the comparison result COMP+ and the comparison result COMP− of the quantizer 440 to the arbiter 103 as a request Req. Furthermore, as described above, the request Req is also input to the exposure enabler 510 including the two AND circuits 511A and 511B connected to the iTOF pixel 310. The OR gate 452 outputs a high-level (e.g., ‘1’) request Req in a case where the address event occurs, and outputs a low-level (e.g., ‘0’) request Req in a case where there is no address event. In addition, an inverted value of the request Req is input to an input terminal D of the flip-flop 454.

The AND gate 453 outputs the logical product of the comparison result COMP− of the quantizer 440 and the response Ack from the arbiter 103 to the column ADC 104 as the detection signal DET−. The AND gate 453 outputs the high-level (e.g., ‘1’) detection signal DET− when the off-event occurs, and outputs the low-level (e.g., ‘0’) detection signal DET− when there is no off-event.

The flip-flop 454 holds the inverted value of the request Req in synchronization with the response Ack. Then, the flip-flop 454 outputs the held value as an internal signal ColEN′ to the input terminal D of the flip-flop 455.

The flip-flop 455 holds the internal signal ColEN′ in synchronization with the selection signal SEL from the drive circuit 102. Then, the flip-flop 455 outputs the held value to the column ADC 104 as the column enable signal ColEN.

1.6 Schematic Configuration Example of iTOF Pixel

FIG. 13 is a circuit diagram illustrating an example of an equivalent circuit of the iTOF pixel according to the present embodiment. As illustrated in FIG. 13, the iTOF pixel 310 has a configuration in which the read voltage Vmixna output from the AND circuit 511A of the exposure enabler 510 is applied to a p+ semiconductor region (hereinafter referred to as MIX) 322 in one signal extraction unit 321A of the two signal extraction units 321A and 321B formed on the semiconductor substrate 324, and the readout circuit 330A including a transfer transistor 332, the floating diffusion region FDn, a reset transistor 331, an amplification transistor 334, and a selection transistor 335 is connected to the n+ semiconductor region (hereinafter referred to as DET) 323.

Similarly, the iTOF pixel 310 has a configuration in which the read voltage Vmixnb output from the AND circuit 511B of the exposure enabler 510 is applied to the MIX 322 in the other signal extraction unit 321B, and the readout circuit 330B including the transfer transistor 332, the floating diffusion region FDn, the reset transistor 331, the amplification transistor 334, and the selection transistor 335 is connected to the DET 323.

Note that the region defined by the two signal extraction units 321A and 321B in the semiconductor substrate 324 functions as a light receiving element of each iTOF pixel 310.

The drive circuit 102 applies the read voltage Vmixna to the MIX 322 of the signal extraction unit 321A and applies the read voltage Vmixnb to the MIX 322 of the signal extraction unit 321B. For example, in a case of extracting a signal (charge) from the signal extraction unit 321A, the drive circuit 102 applies the read voltage Vmixna of 1.5 V (volt) to the MIX 322 of the signal extraction unit 321A, and applies the read voltage Vmixnb of 0 V to the MIX 322 of the signal extraction unit 321B. On the other hand, in a case where the signal (charge) is extracted from the signal extraction unit 321B, the drive circuit 102 applies the read voltage Vmixnb at 1.5 V (volt) to the MIX 322 of the signal extraction unit 321B, and applies the read voltage Vmixna at 0 V to the MIX 322 of the signal extraction unit 321A.

The DET 323 in each of the signal extraction units 321A and 321B is the charge detection unit that detects and accumulates a charge generated by photoelectric conversion of light incident on the semiconductor substrate 324.

In each of the readout circuits 330A and 330B, when a drive signal TRG (na/nb) supplied from the drive circuit 102 to the gate thereof becomes active, the transfer transistor 332 becomes the conductive state in response thereto, thereby transferring the charges accumulated in the corresponding DET 323 to the floating diffusion region FDn.

The floating diffusion region FDn has a charge-voltage conversion function of generating a voltage of a value corresponding to the accumulated charges, and temporarily holds the charges transferred from the DET 323, thereby applying the voltage of a voltage value corresponding to the charge amount to the gate of the amplification transistor 334.

When a drive signal RST (na/nb) supplied from the drive circuit 102 to the gate of the reset transistor 331 becomes active, the reset transistor enters a conductive state in response thereto, thereby resetting the potential of the floating diffusion region FDn to a predetermined level (reset level VRD). When the reset transistor 331 is set to an active state, the transfer transistor 332 is also set to an active state, so that the charges accumulated in the DET 323 can be reset together.

The amplification transistor 334 has a source connected to the vertical signal line (VSL) 403a/403b via the selection transistor 335, thereby configuring a source follower circuit together with the load MOS transistor of the constant current circuit (not illustrated) connected to one end of each of the vertical signal lines (VSL) 403a/403b.

The selection transistor 335 is connected between the source of the amplification transistor 334 and the vertical signal line (VSL) 403a/403b. When the selection signal SEL (na/nb) supplied from the drive circuit 102 to the gate of the selection transistor 335 enters an active state, the selection transistor enters a conductive state in response thereto, and outputs a pixel signal output from the amplification transistor 334 to the vertical signal line (VSL) 403a/403b.

1.7 Drive Control of iTOF Pixel Triggered by Detection of Address Event

In the present embodiment, in the unit pixel 110 in which the address event is detected in the DVS pixel 210, the iTOF pixel 310 is driven to acquire the distance information. Therefore, drive control of the iTOF pixel 310 with detection of the address event in the DVS pixel 210 as a trigger will be described.

1.7.1 Example of Connection Relationship Between DVS Pixel and iTOF Pixel in Unit Pixel

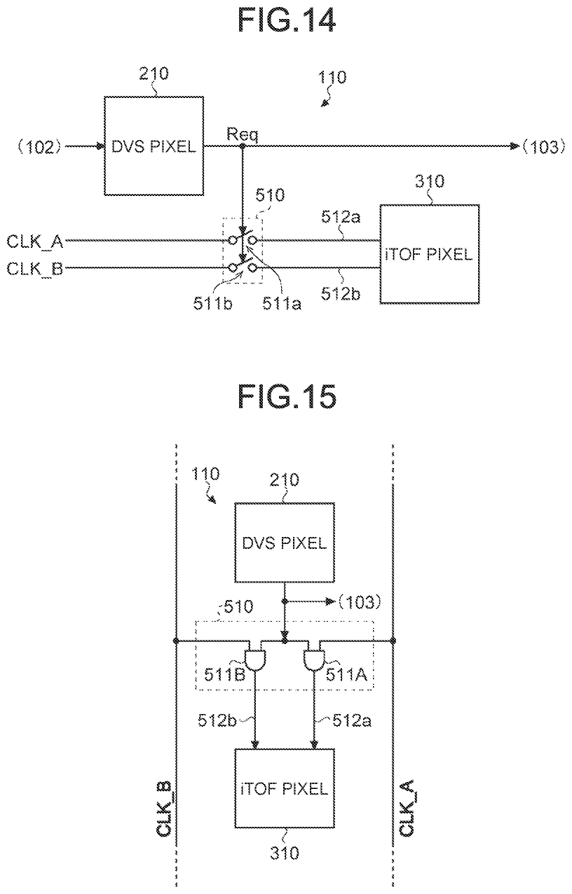

FIG. 14 is a circuit diagram illustrating an example of a connection relationship between the DVS pixel and the iTOF pixel in the unit pixel according to the present embodiment.

As illustrated in FIG. 14, the unit pixel 110 according to the present embodiment includes the exposure enabler 510. For example, the exposure enabler 510 is configured to control whether exposure to the photodiode (PD_iTOF) 220 in the iTOF pixel 310 of the unit pixel 110 is enabled or disabled based on the detection result of the address event by the DVS pixel 210 in each unit pixel 110.

The exposure enabler 510 includes, for example, a switch 511a/511b arranged on a signal line 512a/512b for supplying the read voltage Vmixna/Vmixnb based on a clock signal CLK_A/CLK_B input from the outside to the signal extraction unit 321A/321B (e.g., FIG. 13) in the photodiode (PD_iTOF) 320.

For example, the detection signal (request Req) indicating that the address event is detected from the DVS pixel 210 is input to the switching terminal of the switch 511a/511b. Therefore, in the unit pixel 110 in which the address event is detected in the DVS pixel 210, the clock signal CLK_A/CLK_B (read voltage Vmixna/Vmixnb read therefrom) is supplied to the signal extraction unit 321A/321B of the photodiode (PD_iTOF) 320 via the switch 511a/511b.

1.7.2 Schematic Configuration Example of Exposure Enabler

FIG. 15 is a circuit diagram illustrating a schematic configuration example of the exposure enabler according to the present embodiment. As illustrated in FIG. 15, each of the switches 511a and 511b in the exposure enabler 510 includes, for example, a logical product circuit (hereinafter referred to as an AND circuit).

One AND circuit 511A is an AND circuit for obtaining a logical product of the read voltage Vmixna (corresponding to the clock signal CLK_A) supplied to the signal extraction unit 321A of the photodiode (PD_iTOF) 320 (e.g., FIG. 13) in the iTOF pixel 310 and the detection signal (request Req) output from the DVS pixel 210, and the other AND circuit 511B is an AND circuit for obtaining a logical product of the read voltage Vmixnb (corresponding to the clock signal CLK_B) supplied to the signal extraction unit 321B of the photodiode (PD_iTOF) 320 (e.g., FIG. 13) and the detection signal (request Req) output from the DVS pixel 210.

As described above, in the present embodiment, the pixel signal as the distance information is generated in the iTOF pixel 310 of the unit pixel 110 to which the DVS pixel 210 in which the address event is detected belongs. In other words, the read operation of the pixel signal as the distance information is not executed for the iTOF pixel 310 of the unit pixel 110 in which no address event is detected in the DVS pixel 210.

1.7.3 Supply Configuration Example of Read Voltage

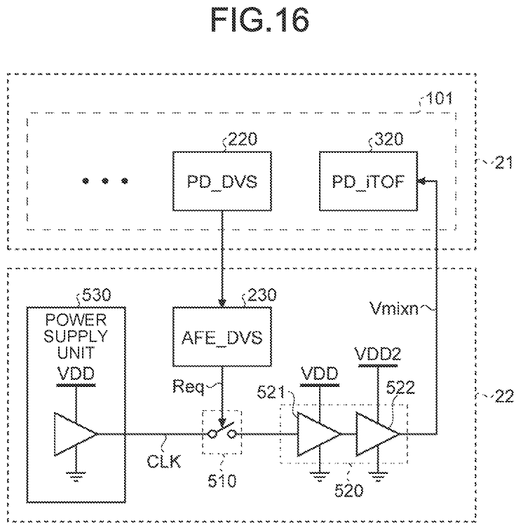

FIG. 16 is a circuit diagram illustrating a supply configuration example of a read voltage according to the present embodiment. As illustrated in FIG. 16, in the present embodiment, the clock signal CLK_A/CLK_B (simply referred to as CLK in the drawing) is supplied from, for example, a power supply unit 530 in a peripheral circuit of the solid-state imaging device 100.

The clock signal CLK_A/CLK_B output from the power supply unit 530 is supplied to the signal extraction unit 321A/321B of the photodiode (PD_iTOF) 320 after passing through the exposure enabler 510, and is boosted to the read voltage Vmixna/Vmixnb (simply referred to as Vmixn in the drawing) of a voltage value necessary for signal extraction in a stage before being supplied to the signal extraction unit 321A/321B.

For boosting the clock signal CLK_A/CLK_B to the read voltage Vmixna/Vmixnb, as illustrated in FIG. 16, a level shifter 520 including a plurality of stages of amplifiers 521 and 522 operating based on different power supply voltages VDD and VDD1, respectively, can be used. The level shifter 520 may be included in the exposure control unit. In the level shifter 520, the drive voltage of the amplifier 521 in the preceding stage may be, for example, the same drive voltage VDD as the power supply unit 530. On the other hand, the drive voltage VDD2 of the amplifier 522 in the subsequent stage may be, for example, a voltage higher than the drive voltage VDD.

Note that the power supply unit 530, the exposure enabler 510, and the level shifter 520 may be arranged, for example, on the circuit chip 22 in the solid-state imaging device 100.

With such a configuration, it is possible to limit the unit pixel 110 (iTOF pixel 310) that executes reading of the pixel signal that is the distance information, and thus, it is possible to perform the read operation at a higher modulation frequency. Furthermore, by narrowing down the unit pixels 110 to those performing reading, there is no need to supply drive power to the unit pixels 110 not performing reading, and thus it is also possible to suppress an increase in power consumption.

1.8 Layout Example of Solid-State Imaging Device

Next, a layout example of the solid-state imaging device 100 according to the present embodiment will be described with some examples.

1.8.1 First Layout Example

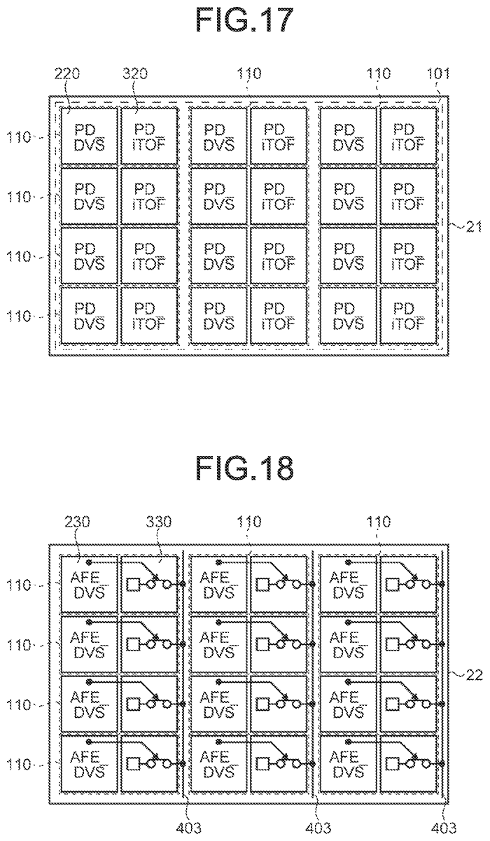

FIG. 17 is a schematic plan view illustrating a schematic configuration example of the light receiving chip side in the solid-state imaging device according to a first layout example of the present embodiment, and FIG. 18 is a schematic plan view illustrating a schematic configuration example of the circuit chip side in the solid-state imaging device according to the first layout example of the present embodiment.

As illustrated in FIG. 17, in the light receiving chip 21 according to the first layout example, the photodiodes (PD_DVS) 220 and the photodiodes (PD_iTOF) 320 are arranged in a two-dimensional lattice pattern so as to be arranged in the column direction (longitudinal direction in the drawing). In this case, the photodiodes (PD_DVS) 220 and the photodiodes (PD_iTOF) 320 are alternately arranged in the row direction (lateral direction in the drawing).

In addition, the address event detection circuit (AFE_DVS) 230 is arranged in a region vertically corresponding to the photodiode (PD_DVS) 220 in the circuit chip 22. Similarly, the readout circuit 330 is arranged in a region vertically corresponding to the photodiode (PD_iTOF) 320 in the circuit chip 22. Therefore, as illustrated in FIG. 18, in the circuit chip 22 according to the first layout example, the address event detection circuits (AFE_DVS) 230 and the readout circuits 330 are arranged in the two-dimensional lattice pattern so as to be arranged in the column direction (longitudinal direction in the drawing). In this case, the address event detection circuit (AFE_DVS) 230 and the readout circuit 330 are alternately arranged in the row direction (lateral direction in the drawing).

1.8.2 Second Layout Example

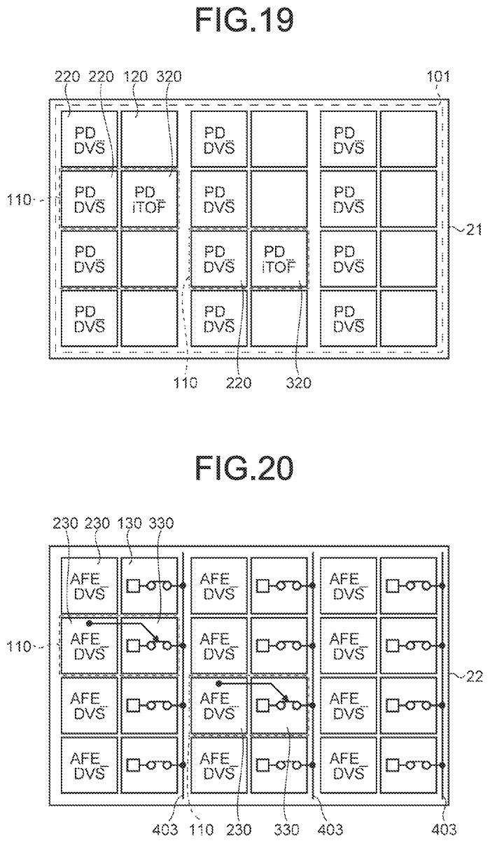

FIG. 19 is a schematic plan view illustrating a schematic configuration example of the light receiving chip side in the solid-state imaging device according to a second layout example of the present embodiment, and FIG. 20 is a schematic plan view illustrating a schematic configuration example of the circuit chip side in the solid-state imaging device according to the second layout example of the present embodiment.

As illustrated in FIG. 19, in the light receiving chip 21 according to the second layout example, some photodiodes (PD_iTOF) 320 in the light receiving chip 21 according to the first layout example are replaced with photodiodes 120 for acquiring pixel values of gradation pixels. Furthermore, as illustrated in FIG. 20, in the circuit chip 22 according to the second layout example, the readout circuit 130 for generating the pixel signal of the pixel value according to the charge generated in the photodiode 120 is arranged in a region vertically corresponding to the photodiode 120 in the light receiving chip 21. In other words, in the second layout example, some of the iTOF pixels 310 are replaced with pixels that acquire pixel values of gradation pixels (hereinafter referred to as gradation pixels).

As described above, the unit pixel 110 that acquires the distance information based on the detection result of the address event by the DVS pixel 210 is not necessarily arranged in the entire pixel array unit 101, and may be arranged in a part thereof. In the second layout example, the DVS pixel 210 not combined with the iTOF pixel 310 may simply operate as a pixel that outputs the detection result of the address event to the outside.

1.8.3 Third Layout Example

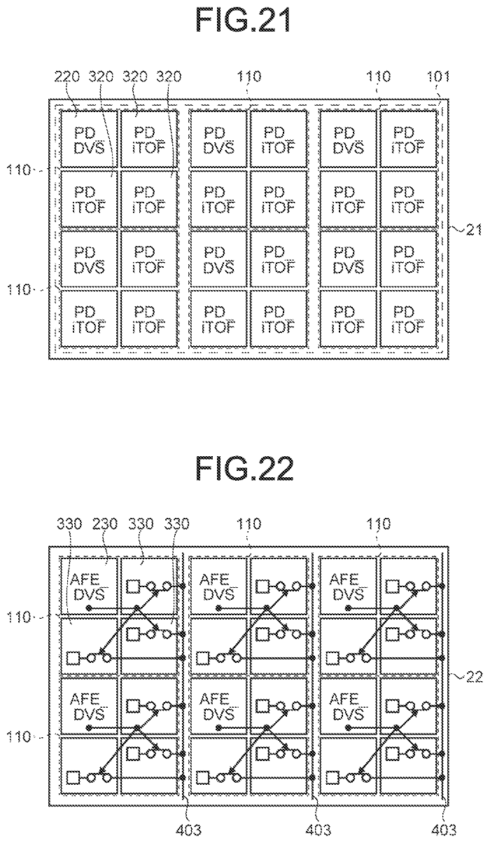

FIG. 21 is a schematic plan view illustrating a schematic configuration example of the light receiving chip side in the solid-state imaging device according to a third layout example of the present embodiment, and FIG. 22 is a schematic plan view illustrating a schematic configuration example of the circuit chip side in the solid-state imaging device according to the third layout example of the present embodiment.

As illustrated in FIG. 21 and FIG. 22, in the third layout example, one unit pixel 110 includes one DVS pixel 210 and a plurality of (in this example, three) iTOF pixels 310. In each unit pixel 110, the photodiode (PD_DVS) 220 and the photodiode (PD_iTOF) 320, and the address event detection circuit (AFE_DVS) 230 and the readout circuit 330 are arranged in a matrix (in this example, 2×2).

In each unit pixel 110, the detection signal (request Req) of the address event output from the DVS pixel 210 is commonly input to all the iTOF pixels 310 belonging to the same unit pixel 110. Therefore, in the third layout example, the distance information is acquired using the plurality of iTOF pixels 310 in the unit pixel 110 in which the DVS pixel 210 has detected the address event. The distance information acquired by each iTOF pixel 310 may be output to the outside as the distance information of different pixels, or may be output to the outside as the distance information of the unit pixel 110 to which the iTOF pixel 310 belongs by taking a total value or an average value of the distance information.

1.8.4 Fourth Layout Example

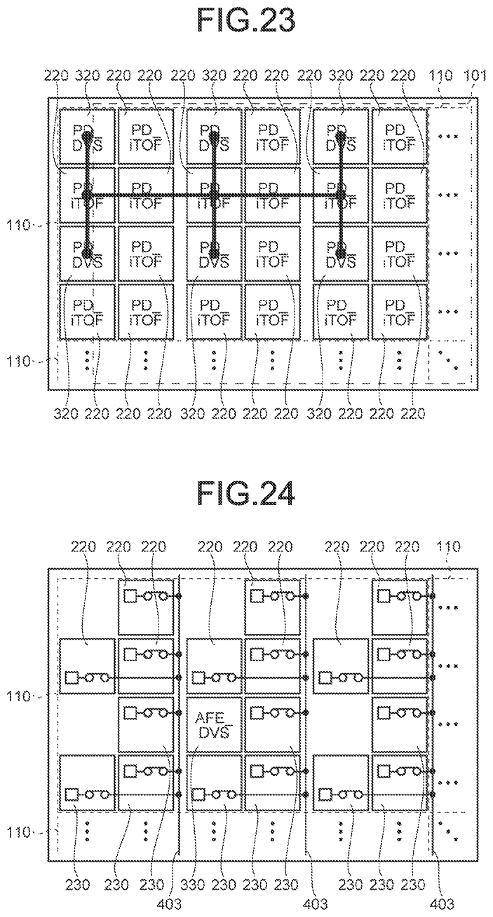

FIG. 23 is a schematic plan view illustrating a schematic configuration example of the light receiving chip side in the solid-state imaging device according to a fourth layout example of the present embodiment, and FIG. 24 is a schematic plan view illustrating a schematic configuration example of the circuit chip side in the solid-state imaging device according to the fourth layout example of the present embodiment.

As illustrated in FIG. 23 and FIG. 24, in the fourth layout example, one unit pixel 110 includes a plurality of (in this example, six) DVS pixels 210 and a plurality of (in this example, 18) iTOF pixels 310. In each unit pixel 110, the photodiode (PD_DVS) 220 and the photodiode (PD_iTOF) 320, and the address event detection circuit (AFE_DVS) 230 and the readout circuit 330 are arranged in a matrix (in this example, 4×6)

As described above, in a case where one unit pixel 110 includes a plurality of DVS pixels 210, the photodiodes (PD_DVS) 220 of the plurality of DVS pixels 210 are preferably arranged evenly in the light receiving chip 21. For example, as illustrated in FIG. 23, the layout may be such that the photodiode (PD_DVS) 220 and the photodiode (PD_iTOF) 320 are alternately arranged in the odd rows and the odd columns.

Furthermore, in a case where one unit pixel 110 includes the plurality of DVS pixels 210, whether or not to drive the iTOF pixel 310 may be controlled based on the total amount of charges generated in the photodiodes (PD_DVS) 220 of the plurality of DVS pixels 210, or whether or not to drive the iTOF pixel 310 may be controlled based on the number of DVS pixels 210 having detected the address event. In the former case, the total amount of charges may be an analog value or a digital value.

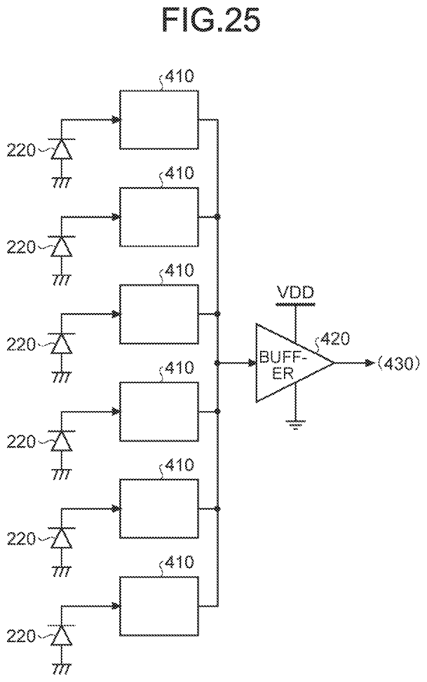

In a case where whether to drive the iTOF pixel 310 is controlled based on the total amount of charges generated in the photodiodes (PD_DVS) 220 of the plurality of DVS pixels 210, as illustrated in FIG. 24, one address event detection circuit (AFE_DVS) 230 may be shared, for example, by the plurality of DVS pixels 210. In this case, as illustrated in FIG. 25, in the address event detection circuit (AFE_DVS) 230, the current-voltage conversion unit 410 may be provided for each of the plurality of photodiodes (PD_DVS) 220 on a one-to-one basis, and the configuration on and after the buffer 420 (buffer 420, subtractor 430, quantizer 440, transfer unit 3450, and the like) may be shared by the plurality of DVS pixels 210.

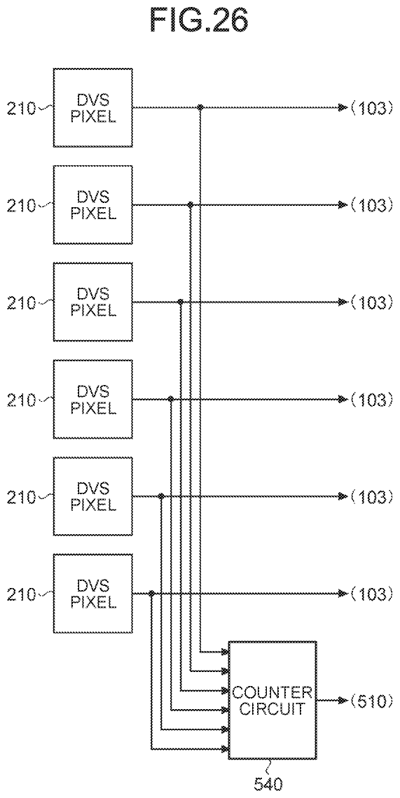

Furthermore, in a case where whether to drive the iTOF pixel 310 is controlled based on the number of DVS pixels 210 in which the address event is detected, as illustrated in FIG. 26, a counter circuit 540 that counts the number of detection signals (requests Req) output from a plurality of address event detection circuits (AFE_DVS) 230 may be provided, and the driving of the iTOF pixel 310 may be permitted when the number of detection signals counted by the counter circuit 540, i.e., the number of DVS pixels 210 in which the address event is detected, exceeds a predetermined threshold. Note that, in this case, the address event detection circuit (AFE_DVS) 230 is arranged in a region on the circuit chip 22 corresponding to each photodiode (PD_DVS) 220 (e.g., FIG. 22).

1.9 Schematic Operation Example of Solid-State Imaging Device

Next, a schematic operation example of the solid-state imaging device 100 according to the present embodiment will be described with reference to a combination example of each DVS pixel 210, each iTOF pixel 310, and a color filter 32.

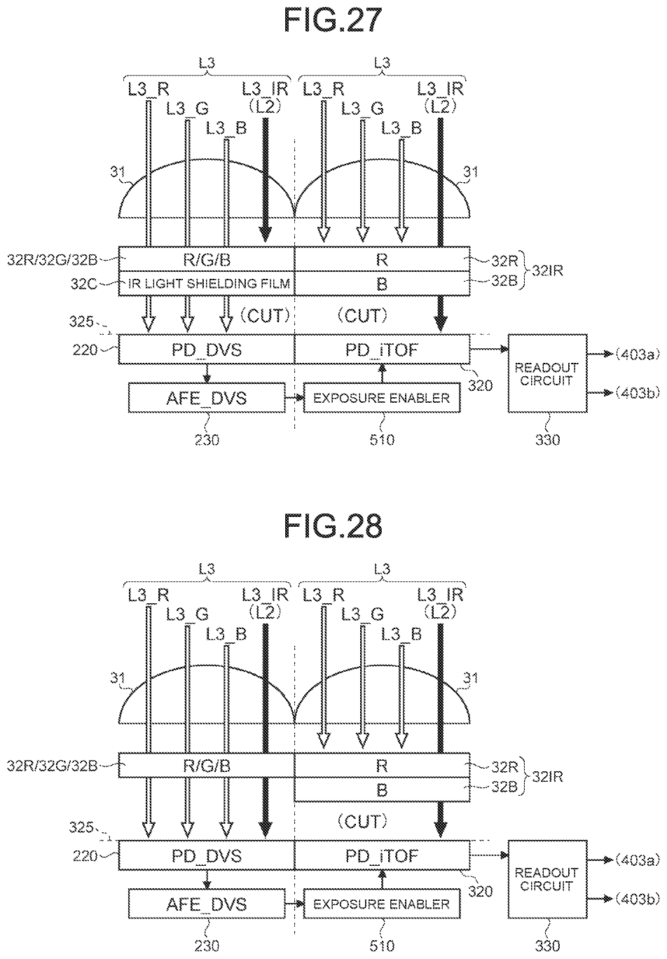

FIG. 27 is a diagram illustrating a schematic operation example of the solid-state imaging device according to the present embodiment. Note that FIG. 27 illustrates a case where a color filter 32R that selectively transmits light in a red wavelength band, a color filter 32G that selectively transmits light in a green wavelength band, and a color filter 32B that selectively transmits light in a blue wavelength band are combined with the photodiode (PD_DVS) 220 of the DVS pixel 210, and a color filter 32IR that selectively transmits infrared light (also referred to as IR light) corresponding to the laser light L1 output from the light source 11 is combined with the photodiode (PD_iTOF) 320 of the iTOF pixel 310. Note that the color filter 32IR may be configured by combining, for example, the color filter 32R and the color filter 32B each having a transmission characteristic in a wavelength band of the IR light.

Furthermore, in the first pattern, the DVS pixel 210 is also combined with an IR light shielding film 32C for shielding the infrared light (IR light).

Note that all of the color filters 32R, 32G, and 32B are not necessarily combined in one DVS pixel 210, and one or two of them may be combined.

Furthermore, in the present example, the case where the color filter to be combined with the DVS pixel 210 is a color filter of the Bayer array has been exemplified, but the color filter is not limited thereto. For example, a color filter including a color filter having a broad light transmission characteristic with respect to the entire visible light (also referred to as a clear, white, or gray color filter), a color filter having a broad light shielding characteristic with respect to the entire visible light (also referred to as a black color filter) may also be used.

Furthermore, instead of the color filter 32 that transmits light of a specific wavelength band, a polarizer or the like that selectively transmits light in a specific polarization state may be used.

When the light L3 including the reflected light L2 is incident on the DVS pixel 210 having such a filter structure, the wavelength component L3_IR corresponding to the reflected light L2 in the light L3 is cut by the IR light shielding film 32C, and one or more of the red wavelength component L3_R, the green wavelength component L3_G, and the blue wavelength component L3_B are incident on the photodiode (PD_DVS) 220.

When the address event detection circuit (AFE_DVS) 230 detects the address event based on the charge generated by the photodiode (PD_DVS) 220 according to the light amount of the wavelength components L3_R, L3_G, and/or L3_B, the address event detection circuit (AFE_DVS) inputs the detection signal (request Req) thereof to the exposure enabler 510. On the other hand, the exposure enabler 510 supplies the read voltages Vmixna and Vmixab obtained by boosting the clock signals CLK_A and CLK_B to the signal extraction units 321A and 321B of the photodiodes (PD_iTOF) 320 in the iTOF pixel 310 during a period in which the detection signal is input. As a result, during a period in which the clock signal CLK_A/CLK_B is at a high level, exposure to the photodiode (PD_iTOF) 320 is permitted, and charges can be extracted from the photodiode (PD_iTOF) 320.

On the other hand, in the iTOF pixel 310, when the light L3 including the reflected light L2 is incident, among the light L3, the wavelength components L3_R, L3_G, and L3_B that are visible light are cut, and the wavelength component L3_IR corresponding to the reflected light L2 is incident on the photodiode (PD_iTOF) 320. Therefore, during a period in which the clock signal CLK_A/CLK_B is at a high level, a charge corresponding to the amount of the reflected light L2 incident on the photodiode (PD_iTOF) 320 is transferred to the readout circuit 330, whereby the pixel signal having a voltage value corresponding to the amount of the reflected light L2 appears in the vertical signal line 403a/403b.

The pixel signal appearing in the vertical signal line 403 is converted into the pixel signal of a digital value by the column ADC 104. This digital value pixel signal is output as the distance information from the signal processing circuit 105 to the external signal processing unit 13.

1.9.1 First Modification

FIG. 28 is a diagram illustrating a first modification of the solid-state imaging device according to the present embodiment. An example illustrated in FIG. 27 exemplifies a case where IR light (wavelength component L3_IR, for example, reflected light L2) incident on the photodiode (PD_DVS) 220 of the DVS pixel 210 is shielded by the IR light shielding film 32C, but the IR light shielding film 32C is omitted in the first modification.

As described above, even in a case where the IR light shielding film 32C is omitted, in other words, even in a case where IR light (wavelength component L3_IR, for example, reflected light L2) is incident on the photodiode (PD_DVS) 220 of the DVS pixel 210, for example, in a case where the distance to the object 90 as a subject is long and the intensity of the reflected light L2 is low, it is possible to suppress the detection of the blinking reflected light L2 by the DVS pixel 210 as an address event, and thus, it is possible to suppress the number of iTOF pixels 310 to be driven. This makes it possible to increase the modulation frequency of the light source 11 while suppressing an increase in power consumption.

1.9.2 Second Modification

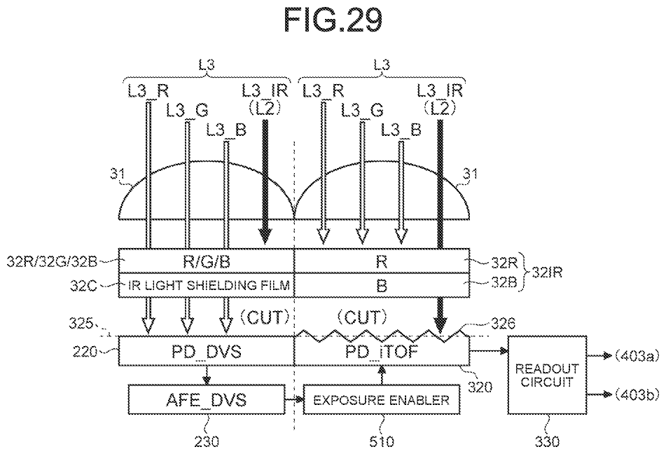

FIG. 29 is a diagram illustrating a second modification of the solid-state imaging device according to the present embodiment. As illustrated in FIG. 29, at least one light receiving surface 325 of the photodiode (PD_DVS) 220 and the photodiode (PD_iTOF) 320 may be provided with an uneven structure (also referred to as a rig) 326. As a result, reflection of the light L3 transmitted through the color filter 32 on the light receiving surface 325 can be suppressed, or an optical path length in the semiconductor substrate 37 can be increased by diffracting the light L3, so that the photoelectric conversion efficiency of the DVS pixel 210 and/or the iTOF pixel 310 can be increased. As a result, the sensitivity of the DVS pixel 210 and/or the iTOF pixel 310 can be increased, so that the distance measurement accuracy can be improved.

1.10 Flowchart of Schematic Operation Example

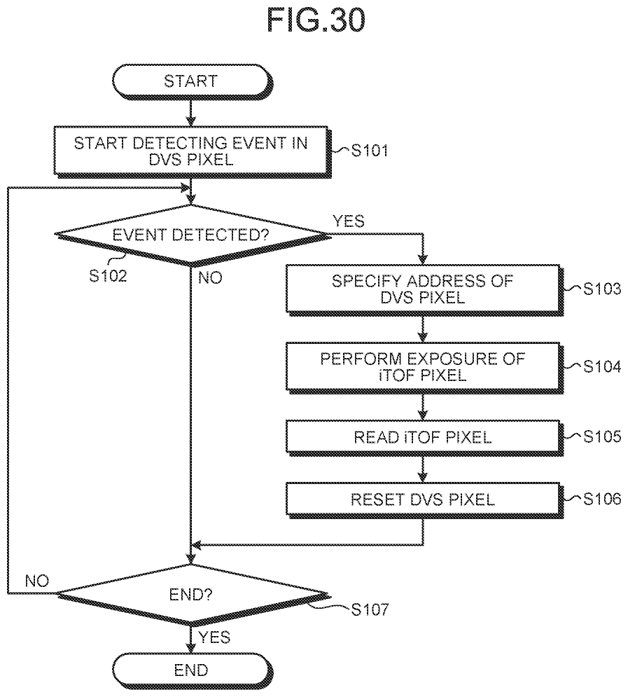

FIG. 30 is a flowchart illustrating a schematic operation example of the solid-state imaging device according to the present embodiment. This operation is started, for example, when an application for detecting and capturing the address event is executed.

As illustrated in FIG. 30, the solid-state imaging device 100 first starts detection of the address event (Step S101), and determines whether or not the address event has been detected (Step S102). The DVS pixel 210 is used to detect the address event. When no address event is detected (NO in Step S102), the operation proceeds to Step S107.

On the other hand, when the address event is detected (YES in Step S102), the arbiter 103 specifies an address of the unit pixel 110 in which the address event has been detected (Step S103).

As described above, when the address of the unit pixel 110 including the DVS pixel 210 in which the address event has been detected is specified, the drive circuit 102 executes an exposure operation on the iTOF pixel 310 belonging to the specified unit pixel 110 (Step S104), and then drives the readout circuit 330 of the iTOF pixel 310 to execute the read operation of the pixel signal (Step S105). Thereafter, the drive circuit 102 performs a reset operation on the DVS pixel 210 (Step S106), and proceeds to Step S107. Note that the reset operation on the DVS pixel 210 may be executed on the DVS pixel 210 in which the address event is detected, or may be executed on all the DVS pixels 210.

In Step S107, the solid-state imaging device 100 determines whether or not to end the present operation, and in a case where the present operation is ended (YES in Step S107), the present operation is ended. On the other hand, when the process is not ended (NO in Step S107), the process returns to Step S102, and the operations of Step S102 and subsequent steps are executed.

1.11 Example of Distance Image Generation Operation

Next, an operation for generating a distance image based on information obtained from the solid-state imaging device 100 according to the present embodiment will be described with some examples.

1.11.1 First Example

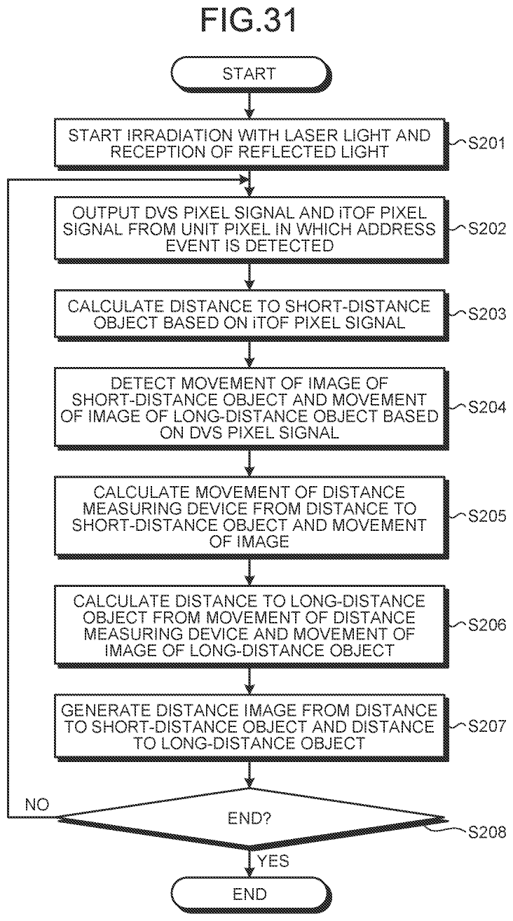

FIG. 31 is a flowchart illustrating an outline of a distance image generation operation according to a first example of the present embodiment. As illustrated in FIG. 31, in the first example, the control unit 12 first starts the operation of the light source 11 and the solid-state imaging device 100 to start irradiation with the laser light L1 from the light source 11 at a predetermined cycle and detection of the address event in the DVS pixel 210 in the solid-state imaging device 100 (Step S201).

As described above, when the irradiation with the laser light L1 and reception of the reflected light L2 start, the solid-state imaging device 100 sequentially outputs the event detection data (hereinafter referred to as a DVS pixel signal) including an X address and a Y address indicating a position of the DVS pixel 210 in which the address event has been detected or a position of the unit pixel 110 including the DVS pixel 210 in the pixel array unit 101, the information related to time (time stamp) when the on-event or the off-event has been detected, and the pixel signal (hereinafter referred to as an iTOF pixel signal) read from the iTOF pixel 310 of the unit pixel 110 including the DVS pixel 210 and converted into the digital value (Step S202). The output event detection data and the iTOF pixel signal are input to, for example, the signal processing unit 13.

Based on the iTOF pixel signal input, the signal processing unit 13 calculates a distance to the object 90 located at a short-distance (hereinafter referred to as a short-distance object) with respect to the distance measuring device 10 (or the solid-state imaging device 100) (Step S203). Note that the short distance may be, for example, a distance less than a predetermined threshold, and the threshold may be a digital value set for the digital iTOF pixel signal. Furthermore, in the following description, the object 90 far from the distance measuring device 10 (or the solid-state imaging device 100) for the threshold or more is referred to as a long-distance object.

Next, the signal processing unit 13 calculates movement of an image of the short-distance object and movement of an image of the long-distance object on a light receiving surface of the solid-state imaging device 100 based on the input DVS pixel signal (Step S204).

Next, the signal processing unit 13 calculates movement of the distance measuring device 10 (or the solid-state imaging device 100) in a real space from the distance to the short-distance object calculated in Step S203 and the movement of the image of the short-distance object calculated in Step S204 (Step S205).

As described above, after calculating the movement of the distance measuring device 10 (or the solid-state imaging device 100) in the real space, the signal processing unit 13 then calculates the distance to the long-distance object from the movement of the distance measuring device 10 (or the solid-state imaging device 100) in the real space and movement of the image of the long-distance object calculated in Step S204 (Step S206).

Next, the signal processing unit 13 generates a distance image for one frame from the distance to the short-distance object calculated in Step S203 and the distance to the long-distance object calculated in Step S206 (Step S207). Note that, for example, the generated distance image may be further subjected to signal processing in the signal processing unit 13, may be input to the control unit 12, may be transmitted to the external host 80 via the I/F unit 15, or may be stored in a storage unit (not illustrated) in the distance measuring device 10.

Thereafter, the control unit 12 determines whether or not to end the present operation (Step S208), and in a case where the present operation is ended (YES in Step S208), the present operation executed in each unit in the distance measuring device 10 is ended. On the other hand, when the processing is not ended (NO in Step S208), the present operation returns to Step S202, and Step S202 and the subsequent steps are executed.

1.11.2 Second Example

The first example described above exemplifies the case where the movement of the distance measuring device 10 (or the solid-state imaging device 100) in the real space is calculated from the distance to the short-distance object calculated based on the iTOF pixel signal and the movement of the image of the short-distance object calculated based on the DVS pixel signal. However, the present invention is not limited to this configuration. For example, the movement of the distance measuring device 10 (or the solid-state imaging device 100) in the real space may be directly detected using an inertial measurement unit (IMU) or the like.

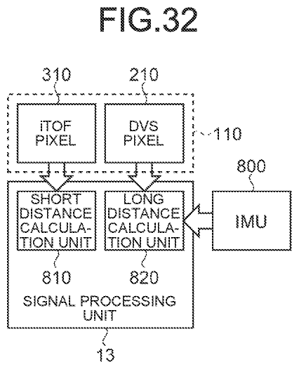

FIG. 32 is a block diagram illustrating a schematic configuration of a solid-state imaging device according to a second example of the present embodiment. As illustrated in FIG. 32, in the second example, the solid-state imaging device 100 includes an IMU 800, and information regarding the movement of the distance measuring device 10 (or the solid-state imaging device 100) detected by the IMU 800 in the real space is input to a long distance calculation unit 820 (e.g., corresponding to a unit that executes the process of Step S206 in FIG. 31) in the signal processing unit 13. Note that a short distance calculation unit 810 in FIG. 32 may correspond to, for example, a unit that executes the process of Step S203 in FIG. 31.

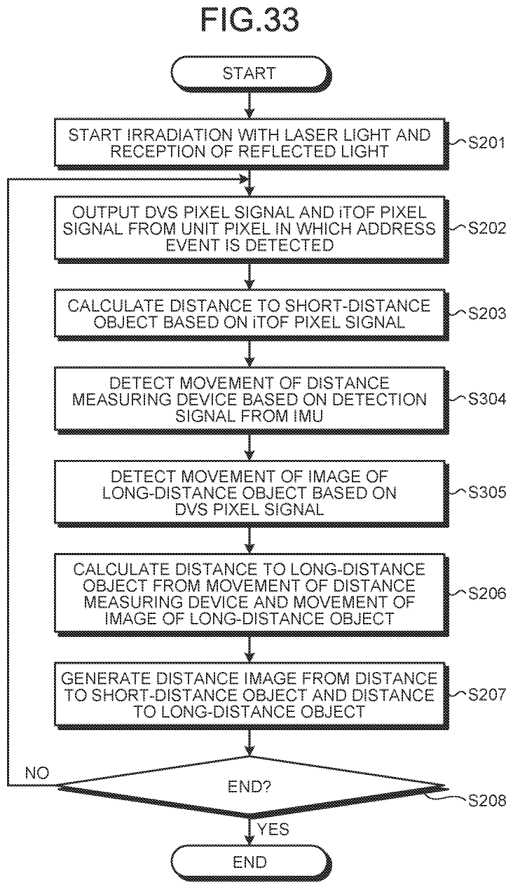

FIG. 33 is a flowchart illustrating an outline of the distance image generation operation according to the second example of the present embodiment. Note that, in FIG. 33, same steps as those in FIG. 31 are cited to omit redundant description thereof.

As can be seen from a comparison between FIG. 33 and FIG. 31, in the second example, the process of Steps S204 to S205 in FIG. 31 is replaced with the process of Steps S304 to S305 in FIG. 33.

In Step S304, the long distance calculation unit 820 in the signal processing unit 13 detects the movement of the distance measuring device 10 (or the solid-state imaging device 100) in the real space based on the detection signal input from the IMU 800.

In Step S305, the signal processing unit 13 calculates the movement of the image of the long-distance object on the light receiving surface of the solid-state imaging device 100 based on the DVS pixel signal input in Step S202.

Thereafter, in the second example, an operation similar to the operation described with reference to Steps S206 to S208 in FIG. 31 in the first example is executed to generate the distance image for one frame. Note that, for example, the generated distance image may be further subjected to signal processing in the signal processing unit 13, may be input to the control unit 12, may be transmitted to the external host 80 via the I/F unit 15, or may be stored in a storage unit (not illustrated) in the distance measuring device 10.

1.11.3 Calculation Method of Distance to Long-Distance Object Based on Movement of Distance Measuring Device and Movement of Image of Long-Distance Object

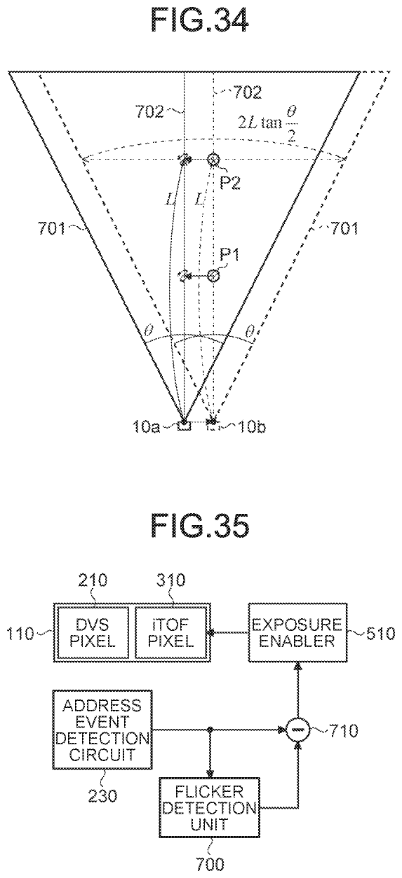

Here, a principle of calculating the distance to the long-distance object from the movement of the distance measuring device 10 (or the solid-state imaging device 100) and the movement of the image of the long-distance object will be described. FIG. 34 is a schematic diagram illustrating the principle of calculating the distance to the long-distance object from movement of the distance measuring device and movement of the image of the long-distance object.

Note that FIG. 34 illustrates a case where the distance measuring device 10 (or the solid-state imaging device 100) horizontally moves from a point 10a to a point 10b at a velocity v in a direction perpendicular to a center line 702 of an angle of view 701 (hereinafter referred to as a lateral direction) of the solid-state imaging device 100.

When a distance L is from the distance measuring device 10 to the long-distance object P2 and an angle θ is a widening angle of view 701, a width in the lateral direction of the angle of view 701 at a time point of the distance L is 2L×tan (θ/2).

Therefore, when an event moving time t per unit pixel 110 is a moving time per unit pixel 110 of the image of the long-distance object P2, and a number N is the number of pixels in the lateral direction of the pixel array unit 101, the distance L to the long-distance object P2 can be obtained from Expression (6) below. Note that the event moving time t per unit pixel 110 may be a time from detecting the address event due to movement of the long-distance object P2 by one DVS pixel 210 of a certain unit pixel 110 to detecting the address event due to movement of the same long-distance object P2 by another DVS pixel 210 of the unit pixel 110 adjacent to the one unit pixel 110 when one unit pixel 110 includes one DVS pixel 210.

$$L = \frac{vNt}{2 tan \frac{θ}{2}} \qquad ( 6 )$$

1.12 Measure Against Flickers

In the above-described configuration, for example, in a case where an object that causes a flicker phenomenon, such as a light source that blinks at a high speed, such as a light emitting diode (LED), an object that reflects the light, or an object that reflects the laser light L1 having a high modulation frequency emitted from the light source 11, is included in the angle of view of the solid-state imaging device 100, there is a possibility that the DVS pixel 210 that has received the light erroneously detects the address event, thereby causing unintended driving of the iTOF pixel 310.

As a countermeasure against such flicker phenomenon, as illustrated in FIG. 35, it is conceivable to provide a flicker detection unit 700 that determines whether or not the detection signal (request Req) output from the address event detection circuit 230 is a detection signal due to the flicker phenomenon.

For example, when the number of detection signals input per unit time exceeds a predetermined threshold or when a periodic detection signal is input, the flicker detection unit 700 determines that the detection signal is a detection signal due to the flicker phenomenon and outputs, for example, a high-level flicker detection signal.

The detection signal (request Req at high level) output from the address event detection circuit 230 and the flicker detection signal (high level) output from the flicker detection unit 700 are input to, for example, a subtractor 710. For example, the flicker detection unit 700 and the subtractor 710 may be included in the exposure control unit. For example, the subtractor 710 subtracts the flicker detection signal (high level) from the detection signal (high level) output from the address event detection circuit 230 during a period in which the high level flicker detection signal is input from the flicker detection unit 700. As a result, since the high-level detection signal (request Req) is not input to the exposure enabler 510 during the period in which the high-level flicker detection signal is input from the flicker detection unit 700, occurrence of unintended driving of the iTOF pixel 310 can be suppressed.

1.13 Summary

As described above, according to the present embodiment, the unit pixels 110 (iTOF pixels 310) to read the pixel signal, which is the distance information, can be limited based on the detection result by the DVS pixel 210. Accordingly, it is possible to perform the read operation at a higher modulation frequency. Furthermore, by narrowing down the unit pixels 110 to those performing reading, there is no need to supply drive power to the unit pixels 110 not performing reading, and thus it is also possible to suppress an increase in power consumption.

### 2. APPLICATION TO MOBILE BODY

The technology according to the present disclosure (present technology) can be applied to various products. For example, the technology according to the present disclosure may be realized as, for example, an apparatus mounted on any type of mobile body such as an automobile, an electric vehicle, a hybrid electric vehicle, a motorcycle, a bicycle, a personal mobility, an airplane, a drone, a ship, and a robot.

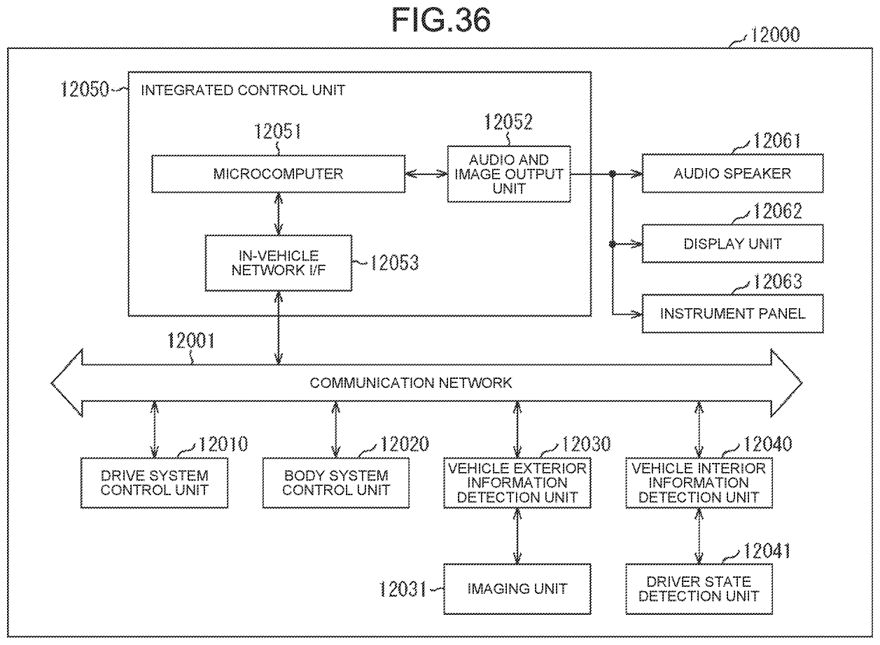

FIG. 36 is a block diagram illustrating a schematic configuration example of a vehicle control system as an example of a moving body control system to which the technology according to the present disclosure can be applied.

A vehicle control system 12000 includes a plurality of electronic control units connected via a communication network 12001. In the example illustrated in FIG. 36, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio and image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device of a driving force generation device for generating a driving force of a vehicle such as an internal combustion engine or a driving motor, a driving force transmission mechanism for transmitting the driving force to wheels, a steering mechanism for adjusting a steering angle of the vehicle, and a braking device for generating a braking force of the vehicle.

The body system control unit 12020 controls operations of various devices mounted on a vehicle body according to various programs. For example, the body system control unit 12020 functions as a control device of a keyless entry system, a smart key system, a power window device, or various lamps including a head lamp, a back lamp, a brake lamp, a blinker, and a fog lamp. In this case, radio waves transmitted from a portable device that substitutes for a key or signals of various switches can be input to the body system control unit 12020. The body system control unit 12020 receives input of these radio waves or signals, and controls a door lock device, a power window device, a lamp, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle, and receives the captured image. The vehicle exterior information detection unit 12030 may perform an object detection process or a distance detection process of a person, a vehicle, an obstacle, a sign, a character on a road surface, or the like based on the received image.

The imaging unit 12031 is an optical sensor that receives light and outputs an electric signal corresponding to an amount of received light. The imaging unit 12031 can output the electric signal as an image or can output the electric signal as distance measurement information. Furthermore, the light received by the imaging unit 12031 may be visible light or invisible light such as infrared rays.

The vehicle interior information detection unit 12040 detects information inside the vehicle. For example, a driver state detection unit 12041 that detects a state of a driver is connected to the vehicle interior information detection unit 12040. The driver state detection unit 12041 includes, for example, a camera that images the driver, and the vehicle interior information detection unit 12040 may calculate a degree of fatigue or a degree of concentration of the driver or may determine whether or not the driver is dozing off based on the detection information input from the driver state detection unit 12041.

The microcomputer 12051 can calculate a target control value of the driving force generation device, the steering mechanism, or the braking device based on the information inside and outside the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an advanced driver assistance system (ADAS) including collision avoidance or impact mitigation of the vehicle, following travel based on an inter-vehicle distance, vehicle speed maintenance travel, vehicle collision warning, vehicle lane departure warning, or the like.

Furthermore, the microcomputer 12051 controls the driving force generation device, the steering mechanism, the braking device, or the like based on the information around the vehicle acquired by the vehicle exterior information detection unit 12030 or the vehicle interior information detection unit 12040, thereby performing cooperative control for the purpose of automatic driving or the like in which the vehicle autonomously travels without depending on the operation by the driver.

Furthermore, the microcomputer 12051 can output a control command to the body system control unit 12020 based on the vehicle exterior information acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio and image output unit 12052 transmits an output signal of at least one of sound or an image to an output device capable of visually or audibly notifying an occupant of the vehicle or the outside of the vehicle of information. In the example in FIG. 36, an audio speaker 12061, a display unit 12062, and an instrument panel 12063 are illustrated as the output device. The display unit 12062 may include, for example, at least one of an on-board display and a head-up display.

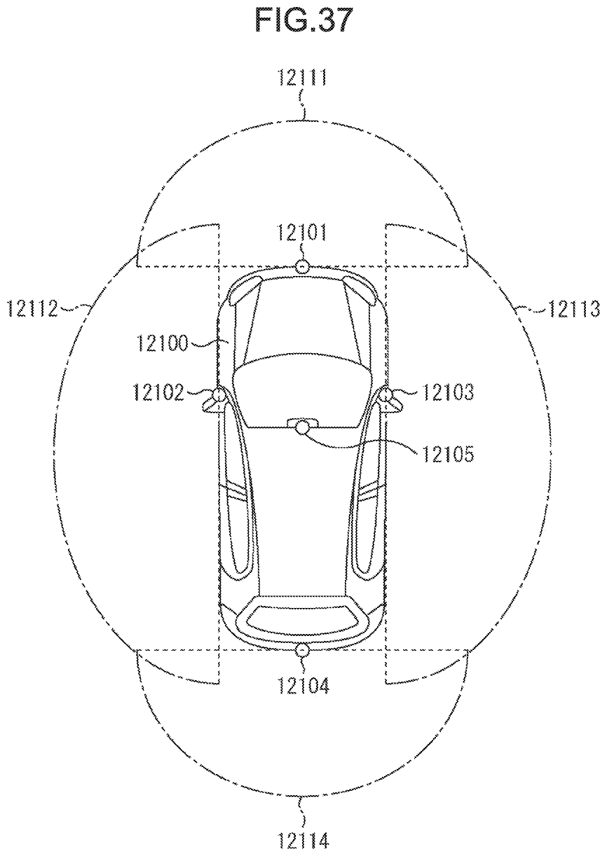

FIG. 37 is a diagram illustrating an example of an installation position of the imaging unit 12031.

In FIG. 37, the imaging unit 12031 includes imaging units 12101, 12102, 12103, 12104, and 12105.

The imaging units 12101, 12102, 12103, 12104, and 12105 are provided, for example, at positions such as a front nose, a side mirror, a rear bumper, a back door, and an upper portion of a windshield in a vehicle interior of a vehicle 12100. The imaging unit 12101 provided at the front nose and the imaging unit 12105 provided at the upper portion of the windshield in the vehicle interior mainly acquire images in front of the vehicle 12100. The imaging units 12102 and 12103 provided at the side mirrors mainly acquire images of the sides of the vehicle 12100. The imaging unit 12104 provided on the rear bumper or the back door mainly acquires an image behind the vehicle 12100. The imaging unit 12105 provided at the upper portion of the windshield in the vehicle interior is mainly used for detecting a preceding vehicle, a pedestrian, an obstacle, a traffic light, a traffic sign, a lane, or the like.

Note that FIG. 37 illustrates an example of imaging ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the side mirrors, respectively, and an imaging range 12114 indicates an imaging range of the imaging unit 12104 provided at the rear bumper or the back door. For example, by superimposing image data captured by the imaging units 12101 to 12104, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 obtains a distance to each three-dimensional object in the imaging ranges 12111 to 12114 and a temporal change of the distance (relative speed with respect to the vehicle 12100) based on the distance information obtained from the imaging units 12101 to 12104, thereby extracting a three-dimensional object traveling at a predetermined speed (e.g., 0 km/h or more) in substantially the same direction as the vehicle 12100, in particular, the closest three-dimensional object on a traveling path of the vehicle 12100. Furthermore, the microcomputer 12051 can set in advance an inter-vehicle distance to be secured with respect to the preceding vehicle, and can perform automatic brake control (including follow-up stop control), automatic acceleration control (including follow-up start control), and the like. As described above, it is possible to perform cooperative control for the purpose of automatic driving or the like in which the vehicle autonomously travels without depending on the operation by the driver.

For example, based on the distance information obtained from the imaging units 12101 to 12104, the microcomputer 12051 can classify three-dimensional object data regarding three-dimensional objects into two-wheeled vehicles, ordinary vehicles, large vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each obstacle, and when the collision risk is a set value or more and there is a possibility of collision, the microcomputer can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not the pedestrian is present in the captured images of the imaging units 12101 to 12104. Such pedestrian recognition is performed by, for example, a procedure of extracting feature points in the captured images of the imaging units 12101 to 12104 as infrared cameras, and a procedure of performing pattern matching processing on a series of feature points indicating an outline of an object to determine whether or not the object is the pedestrian. When the microcomputer 12051 determines that the pedestrian is present in the captured images of the imaging units 12101 to 12104 and recognizes the pedestrian, the audio and image output unit 12052 controls the display unit 12062 to superimpose and display a square contour line for emphasis on the recognized pedestrian. Furthermore, the audio and image output unit 12052 may control the display unit 12062 to display an icon or the like indicating a pedestrian at a desired position.

The example of the vehicle control system to which the technology according to the present disclosure can be applied has been described above. The technology according to the present disclosure can be applied to, for example, the imaging unit 12031 and the like in the configuration described above. Specifically, for example, the distance measuring device 10 in FIG. 1 can be applied to the imaging unit 12031. By applying the technology according to the present disclosure to the imaging unit 12031, it is possible to acquire an accurate distance measurement image while reducing the power consumption of the imaging unit 12031. Accordingly, it is possible to reduce the power consumption of the entire vehicle control system.

Note that the above-described embodiment illustrates an example for embodying the present technology, and matters in the embodiment and the matters used to specify the invention in the claims have a correspondence relationship. Similarly, the matters used to specify the invention in the claims and the matters in the embodiment of the present technology denoted by the same names as the matters used to specify the invention have a correspondence relationship. However, the present technology is not limited to the embodiment, and can be embodied by making various modifications to the embodiment without departing from the gist thereof.

In addition, process procedures described in the above-described embodiment may be regarded as a method including these series of procedures, or may be regarded as a program for causing a computer to execute these series of procedures or a recording medium storing the program. As the recording medium, for example, a compact disc (CD), a mini disc (MD), a digital versatile disc (DVD), a memory card, a Blu-ray (registered trademark) disc, or the like can be used.

Note that the effects described in the present specification are merely examples and not limited, and other effects may be provided.

The present technology can also have the following configurations.

(1)

A solid-state imaging device comprising:

a first pixel configured to detect an address event based on incident light; and

a second pixel configured to generate information on a distance to an object based on the incident light, wherein

the second pixel generates the information on the distance to the object when the first pixel detects the address event.

(2)

The solid-state imaging device according to (1), further comprising

an exposure control unit configured to control exposure of the second pixel, wherein

the exposure control unit permits the exposure of the second pixel when the first pixel detects the address event.

(3)

The solid-state imaging device according to (2), further comprising

a flicker detection unit configured to determine whether a detection result of the address event is due to a flicker phenomenon based on the detection result of the address event by the first pixel, wherein

the exposure control unit prohibits the exposure of the second pixel when the detection result of the address event is due to the flicker phenomenon.

(4)

The solid-state imaging device according to (2) or (3), wherein

the exposure control unit controls the exposure of the second pixel based on a clock signal input from outside.

(5)

The solid-state imaging device according to (4), wherein

the exposure control unit includes a level shifter that boosts the clock signal, and the exposure of the second pixel is controlled by supplying the clock signal boosted by the level shifter to the second pixel.

(6)

The solid-state imaging device according to (5), wherein

the exposure control unit supplies the clock signal boosted by the level shifter to the second pixel when the first pixel detects the address event.

(7)

The solid-state imaging device according to any one of (1) to (6) comprising

a plurality of the first pixels, wherein

the second pixel generates the information on the distance to the object based on a detection result of the address event by the plurality of first pixels.

(8)

The solid-state imaging device according to (7), wherein

the plurality of first pixels includes:

a plurality of photoelectric conversion units corresponding to the plurality of first pixels on a one-to-one basis, each of the plurality of photoelectric conversion units generating a charge based on the incident light, and

a detection circuit shared by the plurality of first pixels, the detection circuit detecting the address event based on the charge generated in the plurality of photoelectric conversion units.

(9)

The solid-state imaging device according to any one of (1) to (8) comprising

a plurality of the second pixels, wherein

each of the plurality of second pixels generates the information on the distance to the object when the first pixel common to the plurality of second pixels detects the address event.

(10)

The solid-state imaging device according to any one of (1) to (9), wherein

at least one of the first pixel and the second pixel has an uneven structure on a surface receiving the incident light.

(11)

The solid-state imaging device according to any one of (1) to (10), wherein

the first pixel includes:

a first photoelectric conversion unit configured to generate a charge according to the incident light, and

a first circuit configured to detect the address event based on the charge generated in the first photoelectric conversion unit,

the second pixel includes:

a second photoelectric conversion unit configured to generate a charge according to the incident light, and

a second circuit configured to generate the information on the distance based on the charge generated in the second photoelectric conversion unit,

the first photoelectric conversion unit and the first photoelectric conversion unit are arranged on a first chip,

the first circuit and the second circuit are arranged on a second chip, and

the first chip and the second chip are bonded to form a single chip.

(12)

A distance measuring device comprising:

a light source configured to emit light having a predetermined wavelength;

a solid-state imaging device; and

a signal processing unit configured to generate a distance image indicating a distance to an object present within an angle of view of the solid-state imaging device, the distance image being generated based on a signal output from the solid-state imaging device, wherein

the solid-state imaging device includes a pixel array unit in which a plurality of pixels is arranged in a matrix,

the pixel array unit includes:

a first pixel configured to detect an address event based on incident light, and

a second pixel configured to generate information on the distance to the object based on the incident light,

the second pixel generates the information on the distance to the object when the first pixel detects the address event, and

the signal processing unit generates the distance image based on the information on the distance generated by the second pixel.

(13)

The distance measuring device according to (12), wherein

the signal processing unit generates the distance image based on movement of the solid-state imaging device in a real space and movement of an image of the object formed on the solid-state imaging device.

(14)

The distance measuring device according to (13), wherein

the signal processing unit detects the movement of the solid-state imaging device in the real space based on a detection result of the address event detected by the first pixel and the information on the distance generated by the second pixel.

(15)

The distance measuring device according to (13), further comprising

a sensor configured to detect the movement of the solid-state imaging device in the real space, wherein

the signal processing unit generates the distance image based on the movement of the solid-state imaging device in the real space detected by the sensor and the movement of the image of the object formed on the solid-state imaging device.

(16)

The distance measuring device according to any one of (12) to (15), wherein

the first pixel includes a light shielding film configured to shield the light having the predetermined wavelength emitted from the light source.

### REFERENCE SIGNS LIST

10 DISTANCE MEASURING DEVICE
11 LIGHT SOURCE
12 CONTROL UNIT
13 SIGNAL PROCESSING UNIT
14 LIGHT SOURCE DRIVE UNIT
15 I/F UNIT
16, 17 OPTICAL SYSTEM
32C IR LIGHT SHIELDING FILM
21 LIGHT RECEIVING CHIP
22 CIRCUIT CHIP
101 PIXEL ARRAY UNIT
102 DRIVE CIRCUIT
103 ARBITER
104 COLUMN ADC
105 SIGNAL PROCESSING CIRCUIT
110 UNIT PIXEL
210 DVS PIXEL
220 PHOTODIODE (PD_DVS)
230 ADDRESS EVENT DETECTION CIRCUIT (AFE_DVS)
310 iTOF PIXEL
320 PHOTODIODE (PD_iTOF)
326 UNEVEN STRUCTURE
330 READOUT CIRCUIT
510 EXPOSURE ENABLER
511a, 511b SWITCH
511A, 511B AND CIRCUIT
520 LEVEL SHIFTER
521, 522 AMPLIFIER
530 POWER SUPPLY UNIT
540 COUNTER CIRCUIT
700 FLICKER DETECTION UNIT
710 SUBTRACTOR
800 IMU
810 SHORT DISTANCE CALCULATION UNIT
820 LONG DISTANCE CALCULATION UNIT
L1 LASER LIGHT
L2 REFLECTED LIGHT
L3 INCIDENT LIGHT

1. A solid-state imaging device comprising:
a first pixel configured to detect an address event based on incident light; and
a second pixel configured to generate information on a distance to an object based on the incident light, wherein
the second pixel generates the information on the distance to the object when the first pixel detects the address event.

2. The solid-state imaging device according to claim 1, further comprising
an exposure control unit configured to control exposure of the second pixel, wherein
the exposure control unit permits the exposure of the second pixel when the first pixel detects the address event.

3. The solid-state imaging device according to claim 2, further comprising
a flicker detection unit configured to determine whether a detection result of the address event is due to a flicker phenomenon based on the detection result of the address event by the first pixel, wherein
the exposure control unit prohibits the exposure of the second pixel when the detection result of the address event is due to the flicker phenomenon.

4. The solid-state imaging device according to claim 2, wherein
the exposure control unit controls the exposure of the second pixel based on a clock signal input from outside.

5. The solid-state imaging device according to claim 4, wherein
the exposure control unit includes a level shifter that boosts the clock signal, and the exposure of the second pixel is controlled by supplying the clock signal boosted by the level shifter to the second pixel.

6. The solid-state imaging device according to claim 5, wherein
the exposure control unit supplies the clock signal boosted by the level shifter to the second pixel when the first pixel detects the address event.

7. The solid-state imaging device according to claim 1 comprising
a plurality of the first pixels, wherein
the second pixel generates the information on the distance to the object based on a detection result of the address event by the plurality of first pixels.

8. The solid-state imaging device according to claim 7, wherein
the plurality of first pixels includes:
a plurality of photoelectric conversion units corresponding to the plurality of first pixels on a one-to-one basis, each of the plurality of photoelectric conversion units generating a charge based on the incident light, and
a detection circuit shared by the plurality of first pixels, the detection circuit detecting the address event based on the charge generated in the plurality of photoelectric conversion units.

9. The solid-state imaging device according to claim 1 comprising
a plurality of the second pixels, wherein
each of the plurality of second pixels generates the information on the distance to the object when the first pixel common to the plurality of second pixels detects the address event.

10. The solid-state imaging device according to claim 1, wherein
at least one of the first pixel and the second pixel has an uneven structure on a surface receiving the incident light.

11. The solid-state imaging device according to claim 1, wherein
the first pixel includes:
a first photoelectric conversion unit configured to generate a charge according to the incident light, and
a first circuit configured to detect the address event based on the charge generated in the first photoelectric conversion unit,
the second pixel includes:
a second photoelectric conversion unit configured to generate a charge according to the incident light, and
a second circuit configured to generate the information on the distance based on the charge generated in the second photoelectric conversion unit,
the first photoelectric conversion unit and the first photoelectric conversion unit are arranged on a first chip,
the first circuit and the second circuit are arranged on a second chip, and
the first chip and the second chip are bonded to form a single chip.

12. A distance measuring device comprising:
a light source configured to emit light having a predetermined wavelength;
a solid-state imaging device; and
a signal processing unit configured to generate a distance image indicating a distance to an object present within an angle of view of the solid-state imaging device, the distance image being generated based on a signal output from the solid-state imaging device, wherein
the solid-state imaging device includes a pixel array unit in which a plurality of pixels is arranged in a matrix,
the pixel array unit includes:
a first pixel configured to detect an address event based on incident light, and
a second pixel configured to generate information on the distance to the object based on the incident light,
the second pixel generates the information on the distance to the object when the first pixel detects the address event, and
the signal processing unit generates the distance image based on the information on the distance generated by the second pixel.

13. The distance measuring device according to claim 12, wherein
the signal processing unit generates the distance image based on movement of the solid-state imaging device in a real space and movement of an image of the object formed on the solid-state imaging device.

14. The distance measuring device according to claim 13, wherein
the signal processing unit detects the movement of the solid-state imaging device in the real space based on a detection result of the address event detected by the first pixel and the information on the distance generated by the second pixel.

15. The distance measuring device according to claim 13, further comprising
a sensor configured to detect the movement of the solid-state imaging device in the real space, wherein
the signal processing unit generates the distance image based on the movement of the solid-state imaging device in the real space detected by the sensor and the movement of the image of the object formed on the solid-state imaging device.

16. The distance measuring device according to claim 12, wherein
the first pixel includes a light shielding film configured to shield the light having the predetermined wavelength emitted from the light source.
